(19) United States
(12) Patent Application Publication
(10) Pub. No.: US 2025/0089519 A1
(43) Pub. Date: Mar. 13, 2025

(54) DISPLAY DEVICE AND METHOD FOR MANUFACTURING THE SAME

(71) Applicant: Samsung Display Co., Ltd., Yongin-si (KR)

(72) Inventors: SUKYOUNG YANG, Yongin-si (KR); JOONYONG PARK, Yongin-si (KR); DONGMIN LEE, Yongin-si (KR)

(21) Appl. No.: 18/741,238

(22) Filed: Jun. 12, 2024

(30) Foreign Application Priority Data
Sep. 8, 2023 (KR) 10-2023-0119342

(51) Int. Cl. H10K 59/80; H10K 59/12; H10K 59/122; H10K 71/16; H10K 71/60; H10K 102/00; H10K 102/10

(52) U.S. Cl. CPC H10K 59/80522; H10K 59/1201; H10K 59/122; H10K 71/164; H10K 71/60; H10K 2102/103; H10K 2102/351

(57) ABSTRACT

A display device including a base layer, a pixel defining film on the base layer and having a light emitting opening defined therein is provided. The display device includes a barrier rib including a first barrier rib layer on the pixel defining film and a second barrier rib layer on the first barrier rib layer. The barrier rib includes a barrier rib opening defined therein and overlapping the light emitting opening. The display device includes a light emitting element overlapping the light emitting opening, and including a first electrode, a light emitting pattern on the first electrode and to emit light, and a second electrode on the light emitting pattern. The display device includes an auxiliary electrode on the second electrode and including a lower auxiliary electrode having indium zinc tin oxide, and a lower auxiliary electrode having indium tin oxide.

### CROSS-REFERENCE TO RELATED APPLICATIONS

This application claims priority to and the benefit of Korean Patent Application No. 10-2023-0119342, filed on Sep. 8, 2023, in the Korean Intellectual Property Office, the entire content of which is incorporated herein by reference.

### BACKGROUND

### 1. Field

The present disclosure herein relates to a display device and a method for manufacturing the same, and, for example, to a display device including an auxiliary electrode.

### 2. Description of the Related Art

Various display devices such as televisions, monitors, smartphones, tablets, and/or the like that provide users with images utilizing, e.g., display panels for displaying the images. As the display panels, a wide variety of display panels such as liquid crystal display panels, organic light emitting display panels, electrowetting display panels, electrophoretic display panels, and/or the like have been under development.

The organic light emitting display panels may include anodes, cathodes, light emitting patterns, and/or the like. The light emitting patterns may be separated for each light emitting region, and the cathodes may provide each light emitting region with a common voltage.

### SUMMARY

One or more aspects of embodiments of the present disclosure is directed toward a display device including an auxiliary electrode having excellent or suitable (e.g., relatively high) light transmittance, and a method for manufacturing the same. Additional aspects will be set forth in part in the description which follows and, in part, will be apparent from the description, or may be learned by practice of the presented embodiments of the disclosure.

One or more embodiments of the present disclosure provides a display device including a base layer, a pixel defining film provided on the base layer and having a light emitting opening defined therein. The barrier rib may include a first barrier rib layer provided on the pixel defining film and a second barrier rib layer provided on the first barrier rib layer. The barrier rib may have a barrier rib opening defined therein, the barrier rib opening overlapping the light emitting opening. The display device may include a light emitting element overlapping the light emitting opening, and including a first electrode, a light emitting pattern provided on the first electrode and to emit (e.g., emitting) light, and a second electrode provided on the light emitting pattern. The display device may include an auxiliary electrode provided on each of the second electrode and (e.g., contacting) the barrier rib, wherein the auxiliary electrode includes a lower auxiliary electrode on (e.g., contacting) each of the second electrode and the barrier rib and comprising (e.g., containing) indium zinc tin oxide (IZTO), and an upper auxiliary electrode provided on the lower auxiliary electrode and comprising (e.g., containing) indium tin oxide (ITO).

In one or more embodiments, the lower auxiliary electrode may have a thickness between (e.g., of or being) equal to or greater than (e.g., at least) about 50 angstrom (Å) and equal to or less than (e.g., at most) about 200 Å.

In one or more embodiments, the upper auxiliary electrode may have a thickness between (e.g., of or being) equal to or greater than (e.g., at least) about 50 Å and equal to or less than (e.g., at most) about 200 Å.

In one or more embodiments, the lower auxiliary electrode may contact (e.g., be on) a first inner surface of the barrier rib opening of the first barrier rib layer and may be electrically connected to the barrier rib.

In one or more embodiments, the upper auxiliary electrode may not be in contact (e.g., be on) with the first barrier rib layer.

In one or more embodiments, the indium zinc tin oxide (IZTO) may have indium atoms and zinc atoms substantially in substantially the same amount, (e.g., an amount of indium atoms may be substantially the same as an amount of zinc atoms) and tin atoms in an amount between equal to or greater than (e.g., at least) about 14 atomic weight percentage (at %) and equal to or less than (e.g., at most) about 22 at % based on a total of 100 at % of IZTO.

In one or more embodiments, the indium tin oxide (ITO) may have indium oxide in a weight percent of about 90 (weight percent) wt % and tin oxide in a weight percent of about 10 wt % based on a total of 100 wt % of ITO.

In one or more embodiments, the second barrier rib layer may include a tip portion protruding from the first barrier rib layer toward the barrier rib opening.

In one or more embodiments, the lower auxiliary electrode and the upper auxiliary electrode may each have an amorphous crystal phase.

In one or more embodiments, the lower auxiliary electrode may extend along each of a first inner surface of the first barrier rib layer and a lower surface of the second barrier rib layer.

In one or more embodiments, the lower auxiliary electrode and the upper auxiliary electrode may each have a light transmittance of equal to or greater than about 90%.

In one or more embodiments of the present disclosure, a display device includes a base layer, a pixel defining film provided on the base layer and having a light emitting opening defined therein. The barrier rib may include a first barrier rib layer provided on the pixel defining film and a second barrier rib layer provided on the first barrier rib layer. The barrier rib may have a barrier rib opening defined therein, the barrier rib opening overlapping the light emitting opening. The display device may include a light emitting element overlapping the light emitting opening, and including a first electrode, a light emitting pattern provided on the first electrode and to emit (e.g., emitting) light, and a second electrode provided on the light emitting pattern. the barrier rib opening overlapping the light emitting opening. The display device may include an auxiliary electrode provided on each of the second electrode and (e.g., contacting) the barrier rib, wherein the auxiliary electrode includes a lower auxiliary electrode on (e.g., contacting) each of the second electrode and the barrier rib, and including a transparent conductive oxide comprising (e.g., containing) zinc, and an upper auxiliary electrode provided on the lower auxiliary electrode and including a transparent conductive oxide.

In one or more embodiments, the lower auxiliary electrode and the upper auxiliary electrode may each have a thickness between (e.g., of or being) equal to or greater than (e.g., at least) about 50 Å and equal to or less than (e.g., at most) about 200 Å.

In one or more embodiments, the lower auxiliary electrode may include indium zinc tin oxide (IZTO), and the upper auxiliary electrode may include indium tin oxide (ITO).

In one or more embodiments, the indium zinc tin oxide (IZTO) may have indium atoms and zinc atoms substantially in substantially the same amount (e.g., an amount of indium atoms may be substantially the same as an amount of zinc atoms), and tin atoms in an amount between (e.g., of or being) equal to or greater than (e.g., at least) about 14 at % and equal to or less than (e.g., at most) about 22 at % based on a total of 100 at % of IZTO.

In one or more embodiments, the lower auxiliary electrode may be on (e.g., contact) a first inner surface of the barrier rib opening of the first barrier rib layer and may be electrically connected to the barrier rib.

In one or more embodiments of the present disclosure, a method for manufacturing a display device includes providing (e.g., applying) a preliminary display panel including a base layer, a pixel defining film provided on the base layer, a first preliminary barrier rib layer provided on the pixel defining film, and a second preliminary barrier rib layer provided on the first preliminary barrier rib layer. The method may include etching the first preliminary barrier rib layer (e.g., to have barrier rib openings) and the second preliminary barrier rib layer (e.g., to have barrier rib openings) to form a first barrier rib layer and a second barrier rib layer (e.g., each) having barrier rib openings defined therein. The method may include forming (e.g., providing or applying) a light emitting element (e.g., in the barrier rib openings) including a first electrode, a light emitting pattern, and a second electrode. The method may include forming (e.g., providing or applying) a lower auxiliary electrode contacting each of the second electrode and the barrier rib, and including (e.g., containing) indium zinc tin oxide (IZTO). The method may include forming (e.g., providing or applying) an upper auxiliary electrode provided on the lower auxiliary electrode and including (e.g., containing) indium tin oxide (ITO).

In one or more embodiments, the forming of the light emitting element, (e.g., forming the light emitting pattern and the second electrode), may each include a thermal evaporation process, and the forming of the lower auxiliary electrode and the upper auxiliary electrode may each include a sputtering process.

In one or more embodiments, the lower auxiliary electrode and the upper auxiliary electrode may each have a thickness between equal to or greater than about 50 Å and equal to or less than about 200 Å.

In one or more embodiments, the lower auxiliary electrode and the upper auxiliary electrode may each have (e.g., include) an amorphous crystal phase.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view of a display device according to one or more embodiments of the present disclosure;

FIG. 2 is an exploded perspective view of a display device according to one or more embodiments of the present disclosure;

FIG. 3 is a cross-sectional view of a display module according to one or more embodiments of the present disclosure;

FIG. 4 is a plan view of a display panel according to one or more embodiments of the present disclosure;

FIG. 5 is an equivalent circuit diagram of pixels according to one or more embodiments of the present disclosure;

FIG. 6 is a plan view of an enlarged portion of a display region of a display panel according to one or more embodiments of the present disclosure;

FIG. 7 is a cross-sectional view of a display panel taken along line I-I′ of FIG. 4 according to one or more embodiments of the present disclosure;

FIG. 8 is a view of an enlarged region AA′ of FIG. 7 according to one or more embodiments of the present disclosure;

FIG. 9 is a cross-sectional view taken along line II-II′ of FIG. 6 according to one or more embodiments of the present disclosure; and

FIGS. 10A-10I are cross-sectional views each showing a portion of a method for manufacturing a display device according to one or more embodiments of the present disclosure.

### DETAILED DESCRIPTION

The present disclosure may be modified in many alternate forms, and thus specific embodiments will be exemplified in the drawings and described in more detail in the detailed description. It should be understood, however, that it is not intended to limit the present disclosure to the particular forms disclosed, but rather, is intended to cover all modifications, equivalents, and alternatives falling within the spirit and scope of the present disclosure.

As utilized herein, when an element (or a region, a layer, a portion, and/or the like) is referred to as being “on,” “connected to,” or “bonded to” another element, it refers to that the element may be directly provided on/connected to/bonded to the other element, or that a third element may be provided therebetween.

When explaining each of drawings, like reference numerals refer to like elements. In one or more embodiments, in the drawings, the thickness, the ratio, and the dimensions of elements are exaggerated for an effective description of technical contents.

As utilized herein, the terms “use,” “using,” and “used” may be considered synonymous with the terms “utilize,” “utilizing,” and “utilized,” respectively.

As utilized herein, expressions such as “at least one of,” “one of,” “selected from,” and “selected from among,” when preceding a list of elements, modify the entire list of elements and do not modify the individual elements of the list. For example, the expressions “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The term “and/or,” includes all combinations of one or more of which associated configurations may define.

It will be understood that, although the terms “first,” “second,” and/or the like may be utilized herein to describe one or more suitable elements, these elements should not be limited by these terms. These terms are only utilized to distinguish one element from another element. For example, a first element may be referred to as a second element, and similarly, a second element may be referred to as a first element without departing from the teachings of the present disclosure. The singular forms “a,” “an,” and “the” are intended to include the plural forms as well, unless the context clearly indicates otherwise.

The terms of “below”, “on lower side”, “above”, “on upper side”, and/or the like may be utilized to describe the relationships of the components shown in the drawings. The terms are utilized as a relative concept and are described with reference to the direction indicated in the drawings. It will be understood that the terms have a relative concept and are described on the basis of the orientation depicted in the drawings. It will be understood that the spatially relative terms are intended to encompass different orientations of the device in use or operation in addition to the orientation depicted in the drawings. For example, if (e.g., when) the device in the drawings is turned over, elements described as “beneath” other elements or features would then be oriented “above” or “over” the other elements or features. Thus, the term “beneath” may encompass both an orientation of above and below. The device may be otherwise oriented (rotated 90 degrees or at other orientations), and the spatially relative descriptors used herein should be interpreted accordingly.

It should be understood that the terms “include,” “includes,” “including,” “comprise,” “comprises”, “comprising,” “has,” “having,” and/or “have” are intended to specify the presence of stated features, integers, steps, operations, elements, components, or combinations thereof in the disclosure, but do not preclude the presence or addition of one or more other features, integers, steps, operations, elements, components, or combinations thereof.

As utilized herein, the term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Unless otherwise defined, all terms (including chemical, technical and scientific terms) utilized herein have the same meaning as commonly understood by one of ordinary skill in the art to which the present disclosure pertains. It is also to be understood that terms defined in commonly utilized dictionaries should be interpreted as having meanings consistent with the meanings in the context of the related art, and are expressly defined herein unless they are interpreted in an ideal or overly formal sense. In one or more embodiments, terms, such as those defined in commonly utilized dictionaries, should be interpreted as having a meaning that is consistent with their meaning in the context of the relevant art and should not be interpreted in an idealized or overly formal sense unless expressly so defined herein.

As utilized herein, the phrase “consisting essentially of” means that any additional components will not materially affect the chemical, physical, optical, or electrical properties of the semiconductor film.

As utilized herein, the phrase “on a plane,” or “plan view,” refers to viewing a target portion from the top, and the phrase “on a cross-section” means viewing a cross-section formed by vertically cutting a target portion from the side.

In present disclosure, “not include a or any ‘component’”, “exclude a or any ‘component’”, “‘component’-free”, and/or the like refers to that the “component” not being added, selected or utilized as a component in the composition/structure, but the “component” of less than a suitable amount may still be included due to other impurities and/or external factor.

The term “at %,” as utilized herein, may be an “atomic weight percentage” that is the percentage of the atomic weight of an element based on a total atomic weight of each element in a compound, and/or the like.

Hereinafter, embodiments of the present disclosure will be described with reference to the accompanying drawings.

### Display Device

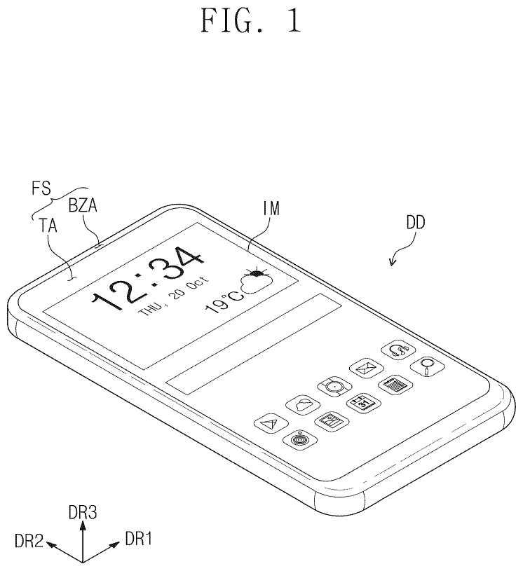

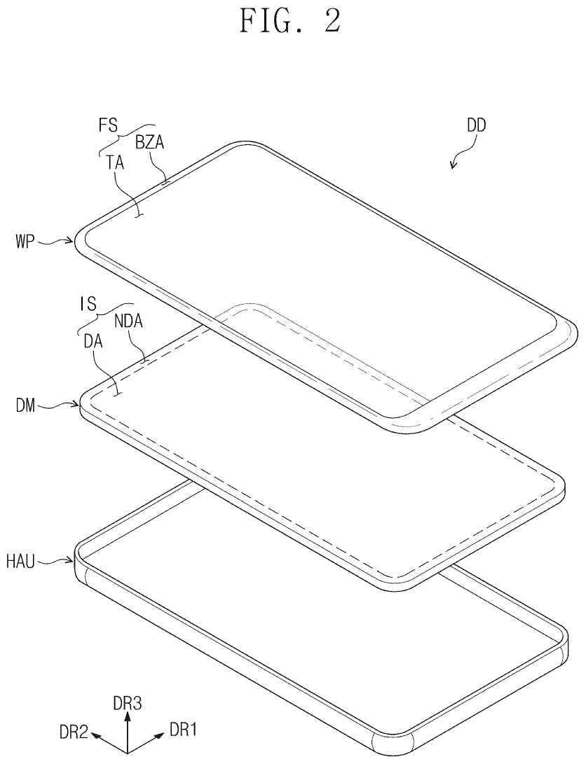

FIG. 1 is a perspective view of a display device according to one or more embodiments of the present disclosure; FIG. 2 is an exploded perspective view of a display device according to one or more embodiments of the present disclosure.

FIG. 1 is a perspective view of a display device DD according to one or more embodiments of the present disclosure, and FIG. 2 is an exploded perspective view of a display device DD according to one or more embodiments of the present disclosure.

In one or more embodiments, the display device DD may be a large-sized electronic device such as a television set, a monitor, an outdoor billboard, and/or the like. In one or more embodiments, the display device DD may be a small- and medium-sized electronic device such as personal computers, laptop computers, personal digital terminals, car navigation systems, game consoles, smart phones, tablets, and cameras. However, these are merely presented as an example, and thus it may be adopted for other display devices without departing from the present disclosure. As an example, a smartphone is shown as the display device DD in FIGS. 1 and 2.

Referring to FIGS. 1 and 2, the display device DD may display an image IM toward a third direction DR3, on a display surface FS, the display surface FS being parallel to each of a first direction DR1 and a second direction DR2. The third direction DR3 may be a normal direction with respect to a plane defined by the first direction DR1 and/or the second direction DR2. The image IM may include still images as well as dynamic images. In FIG. 1, a watch window and icons are shown as an example of the image IM. The display surface FS on which the image IM is displayed may correspond to a front surface of the display device DD.

In the present embodiment, a front surface (or an upper surface) and a rear surface (or a lower surface) of respective members are defined with respect to a direction in which the image IM is displayed. Front and rear surfaces may oppose each other in the third direction DR3 and a normal direction of each of the front and rear surfaces may be parallel to the third direction DR3. In one or more embodiments, directions indicated by the first to third directions DR1, DR2, and DR3 are relative concepts, and may thus be changed to other directions. Herein, “when viewed on a plane” may be defined as viewed from the third direction DR3.

The display device DD may include a window WP, a display module DM, and a housing HAU. The window WP and the housing HAU may be bonded to form an outer portion of the display device DD.

The window WP may include an optically transparent insulating material. For example, the window WP may include glass and/or plastic. A front surface of the window WP may define the display surface FS of the display device DD. The display surface FS may include a transmission region TA and a bezel region BZA. The transmission region TA may be an optically transparent region. For example, the transmission region TA may be a region having a visible light transmittance of about 90% or greater.

The bezel region BZA may be a region having a relatively lower light transmittance, e.g., a light transmittance lower than that of the transmission region TA. The bezel region BZA may define a shape of the transmission region TA. The bezel region BZA may be adjacent to the transmission region TA and may be around (e.g., surround) the transmission region TA. However, this is shown as an example, and the bezel region BZA of the window WP may not be provided. The window WP may include at least (e.g., any) one functional layer selected from among an anti-fingerprint layer, a hard coating layer, and an anti-reflection layer, however it is not limited to any one embodiment.

The display module DM may be provided (e.g., below) the window WP. The display module DM may be configured to substantially generate the image IM. The image IM generated from the display module DM may be displayed on the display surface IS of the display module DM and may be viewed by users from the outside through the transmission region TA.

The display module DM may include a display region DP and a non-display region NDA. The display region DA may be a region activated according to electrical signals. The non-display region NDA may be adjacent to the display region DA. The non-display region NDA may be around (e.g., surround) the display region DA. The non-display region NDA may be a region covered by the bezel region BZA, and thus may not be viewed from the outside.

The housing HAU may be bonded to the window WP. The housing HAU may be bonded to the window WP to provide a set or predetermined inner space. The display module DM may be accommodated (e.g., located) in the inner space.

The housing HAU may include a material having relatively high rigidity. For example, the housing HAU may include a plurality of frames and/or plates including glass, plastic, and/or metal, or may be formed from a combination thereof. The housing HAU may stably protect components of the display device DD, which are accommodated (e.g., located) in the internal space, against external impacts.

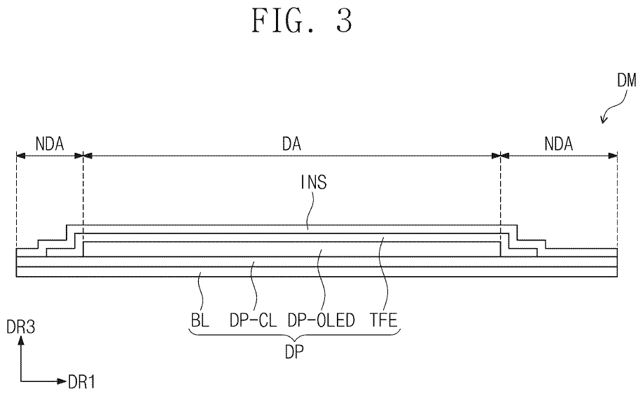

FIG. 3 is a cross-sectional view of a display module according to one or more embodiments of the present disclosure.

Referring to FIG. 3, the display module DM may include a display panel DP and an input sensor INS. According to one or more embodiments, the display device DD (see FIG. 1) of the present disclosure may further include a protection member provided on a lower surface of the display panel DP and/or an anti-reflection member provided on an upper surface of the input sensor INS and/or a window member.

The display panel DP may be a light emitting display panel. However, this is presented as an example, and the embodiment of the present disclosure is not limited thereto. For example, the display panel DP may be an organic light emitting display panel or an inorganic light emitting display panel. An emission layer in the organic light emitting display panel may include an organic light emitting material. An emission layer in in the inorganic light emitting display panel may include quantum dots, quantum rods, micro LEDs, and/or the like. Hereinafter, the display panel DP will be described as an organic light emitting display panel.

The display panel DP may include a base layer BL, a circuit element layer DP-CL provided on the base layer BL, a display element layer DP-OLED, and a thin film encapsulation layer TFE. The input sensor INS may be directly provided on the thin film encapsulation layer TFE. Herein, “a component A is provided directly on a component B” indicates that an adhesive layer is not provided between the component A and the component B.

The base layer BL may include at least one plastic film. The base layer BL may include a plastic substrate, a glass substrate, a metal substrate, an organic/inorganic composite material substrate and/or the like as a flexible substrate. The display region DA and the non-display region NDA described in FIG. 2 may be defined identically in the base layer BL.

The circuit element layer DP-CL may include at least one insulating layer and a circuit element. The insulating layer include at least one inorganic layer and at least one organic layer. The circuit element includes signal lines, pixel driving circuits, and/or the like.

The display element layer DP-OLED may include a barrier rib and a light emitting element. The light emitting element may include an anode, an intermediate layer, and a cathode.

The thin film encapsulation layer TFE may include a plurality of thin films. Some thin films may be provided to increase optical efficiency, and some thin films may be provided to protect organic light emitting diodes.

The input sensor INS acquires information on coordinates of external inputs. The input sensor INS have a multi-layer structure. The input sensor INS may have a single-layer conductive layer or a multi-layer conductive layer. In one or more embodiments, the input sensor INS may include a single insulating layer or a multi-layer insulating layer. The input sensor INS may detect external inputs in a capacitive mode. However, this is presented as an example, and the embodiment of the present disclosure is not limited thereto. For example, in one or more embodiments, the input sensor INS may detect external inputs through a method of electromagnetic induction or a method of pressure sensing. In one or more embodiments of the present disclosure, the input sensor INS may not be provided.

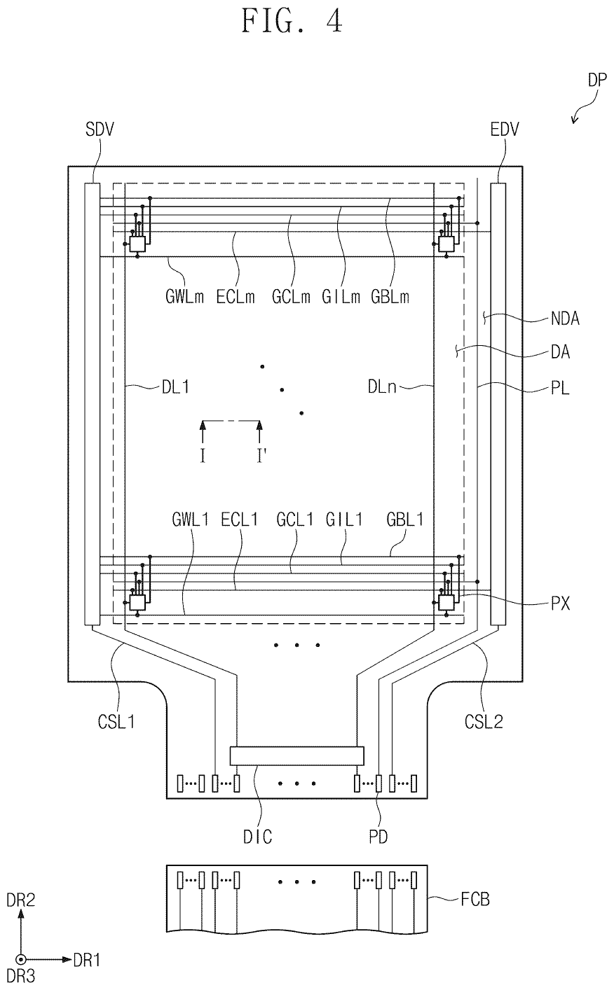

FIG. 4 is a plan view of a display panel according to one or more embodiments of the present disclosure.

Referring to FIG. 4, in the display panel DP, a display region DA and a non-display region NDA around the display region DA may be defined. The display region DA and the non-display region NDA may be defined with respect to presence and/or absence of pixels PX. For example, the pixels PX may be provided in the display region DA, and the pixels PX may not be provided in the non-display region NDA.

The display panel DP may include the pixels PX, initialization scan lines GIL1 to GILm, compensation scan lines GCL1 to GCLm, write scan lines GWL1 to GWLm, black scan lines GBL1 to GBLm, light emitting control lines ECL1 to ECLm, data lines DL1 to DLn, first and second control lines CSL1 and CSL2, a driving voltage line PL, a scan driver SDV, a data driver, a light emitting driver EDV, a driving chip DIC, and pads PD. In this case, m and n may each independently be a natural number of 2 or greater. The data driver may be some of the circuits configured in the driving chip DIC.

The pixels PX may be connected to the initialization scan lines GIL1 to GILm, the compensation scan lines GCL1 to GCLm, the write scan lines GWL1 to GWLm, the black scan lines GBL1 to GBLm, the light emitting control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in the first direction DR1, and be electrically connected to the scan driver SDV. The data lines DL1 to DLn may extend in the second direction DR2 and be electrically connected to the driving chip DIC. The light emitting control lines ECL1 to ECLm may extend in the first direction DR1 and be electrically connected to the light emitting driver EDV.

The driving voltage line PL may include a portion extending in the first direction DR1 and a portion extending in the second direction DR2. The portion extending in the first direction DR1 and the portion extending in the second direction DR2 may be provided on different layers. The driving voltage line PL may provide a driving voltage to the pixels PX.

A first control line CSL1 may be connected to the scan driver SDV. A second control line CSL2 may be connected to the light emitting driver EDV.

The driving chip DIC, the driving voltage line PL, the first control line CSL1, and the second control line CSL2 may be electrically connected to the pads PD. A flexible circuit film FCB may be electrically connected to the pads PD through an anisotropic conductive adhesive layer. The pads PD may be pads for electrically connecting the flexible circuit film FCB to the display panel DP. The pads PD may be connected to the corresponding pixels PX through the driving voltage line PL, the first control line CSL1, and the second control line CSL2.

In one or more embodiments, the pads PD may further include input pads. The input pads may be pads for connecting the flexible circuit film FCB to the input sensor INS (see FIG. 3). However, the embodiment of the present disclosure is not limited thereto, and the input pads may be provided on the input sensor INS and connected to the pads PD and a separate circuit board. In one or more embodiments, the input sensor INS may not be provided and no further input pads may be included.

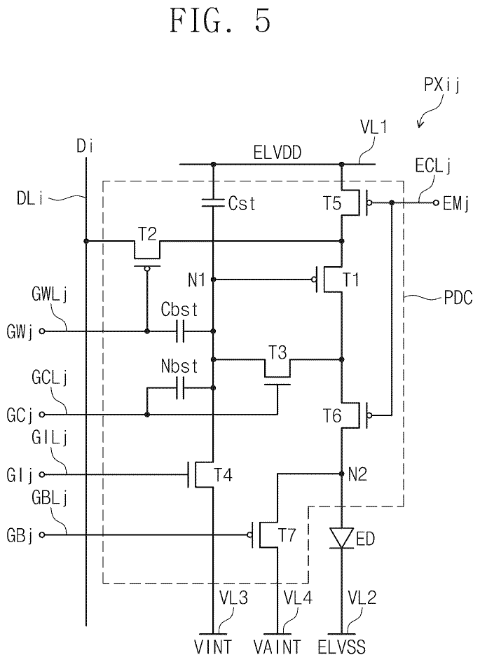

FIG. 5 is an equivalent circuit diagram of pixels according to one or more embodiments of the present disclosure.

FIG. 5 shows an equivalent circuit diagram of one pixel PXij among the plurality of pixels PX (see FIG. 4) as an example. The plurality of pixels PX may each share the same circuit structure, and thus detailed descriptions of the other pixels PX will not be given as the descriptions of the circuit structure of the pixel PXij are replaced (e.g., otherwise equivalent).

Referring to FIGS. 4 and 5, the pixel PXij may be connected to an i-th data line DLi among the data lines DL1 to DLn, a j-th initialization scan line GILj among the initialization scan lines GIL1 to GILm, a j-th compensation scan line GCLj among the compensation scan lines GCL1 to GCLm, a j-th write scan line GWLj among the write scan lines GWL1 to GWLm, a j-th black scan line GBLj among the black scan lines GBL1 to GBLm, a j-th light emitting control line ECLj among the light emitting control lines ECL1 to ECLm, the first and second driving voltage lines VL1 and VL2, and the first and second initialization voltage lines VL3 and VL4. In one or more embodiments, i may be an integer of 1 to n, and j may be an integer of 1 to m.

The pixel PXij includes a light emitting element ED and a pixel circuit PDC. The light emitting element ED may be a light emitting diode. As an example of the present disclosure, the light emitting element ED may be an organic light emitting diode including an organic emission layer, but is not particularly limited thereto. The pixel circuit PDC may control the amount of current flowing through the light emitting element ED in response to a data signal Di. The light emitting element ED may be to emit light with a set or predetermined luminance in response to the amount of current provided from the pixel circuit PDC.

The pixel circuit PDC may include first to seventh transistors T1, T2, T3, T4, T5, T6, and T7, and first to third capacitors Cst, Cbst, and Nbst. The components of the pixel circuit PDC according to one or more embodiments of the present disclosure are not limited to the embodiment shown in FIG. 5. The pixel circuit PDC shown in FIG. 5 is merely an example, and the components of the pixel circuit PDC may include one or more suitable configurations and/or operations.

At least one selected from among the first to seventh transistors T1, T2, T3, T4, T5, T6, and T7 may be a transistor having a low-temperature polycrystalline silicon (LTPS) semiconductor layer. At least one selected from among the first to seventh transistors T1, T2, T3, T4, T5, T6, and T7 may be a transistor having an oxide semiconductor layer. For example, the third and fourth transistors T3 and T4 may be oxide semiconductor transistors, and the first, second, fifth, sixth, and seventh transistors T1, T2, T5, T6, and T7 may be LTPS transistors.

For example, the first transistor T1 that directly affects the brightness of the light emitting element ED is configured to include a semiconductor layer formed of polycrystalline silicon having high reliability, and accordingly, a relatively high resolution display device may be obtained. In one or more embodiments, the oxide semiconductor may have relatively high carrier mobility and low leakage current, and accordingly may not experience a substantially large voltage drop even with relatively long driving time. For example, the color change of images according to the voltage drop may not be substantially large (e.g., drastic) even upon relatively low-frequency driving, and thus relatively low-frequency driving may be allowed. As described herein, the oxide semiconductor provides a benefit of low leakage current, and thus at least one selected from among the third transistor T3 and/or the fourth transistor T4 (e.g., connected to a gate electrode of the first transistor T1) may be employed as an oxide semiconductor to prevent or reduce the leakage current (e.g., that may flow to the gate electrode and to reduce power consumption).

At least one selected from among the first to seventh transistors T1, T2, T3, T4, T5, T6, and T7 may be P-type or kind transistors, and the others (any remaining first to seventh transistors T1, T2, T3, T4, T5, T6, and T7) may be N-type or kind transistors. For example, the first, second, fifth, sixth, and seventh transistors T1, T2, T5, T6, and T7 may be P-type or kind transistors, and the third and fourth transistors T3 and T4 may be N-type or kind transistors.

The components of the pixel circuit PDC according to one or more embodiments of the present disclosure are not limited to the embodiment shown in FIG. 5. The pixel circuit PDC shown in FIG. 5 is merely an example, and the components of the pixel circuit PDC may include one or more suitable configurations and/or operations. For example, the first to seventh transistors T1, T2, T3, T4, T5, T6, and T7 may all be P-type or kind transistors or N-type or kind transistors. In one or more embodiments, the first, second, fifth, and sixth transistors T1, T2, T5, and T6 may be P-type or kind transistors, and the third, fourth, and seventh transistors T3, T4, and T7 may be N-type or kind transistor.

The j-th initialization scan line GILj, the j-th compensation scan line GCLj, the j-th write scan line GWLj, the j-th black scan line SBLj, and the j-th light emitting control line ECLj may be to transmit a j-th initialization scan signal GIj, a j-th compensation scan signal GCj, a j-th write scan signal GWj, a j-th black scan signal GBj, and a j-th light emitting control signal EMj to the pixel PXij, respectively. The i-th data line DLi transmits an i-th data signal Di to the pixel PXij. The i-th data signal Di may have a voltage level corresponding to an image signal input to the display device DD (see FIG. 1).

The first and second driving voltage lines VL1 and VL2 may be to transmit a first driving voltage ELVDD and a second driving voltage ELVSS to the pixel PXij, respectively. In one or more embodiments, the first and second initialization voltage lines VL3 and VL4 may be to transmit a first initialization voltage VINT and a second initialization voltage VAINT to the pixel PXij, respectively.

The first transistor T1 is connected between the first driving voltage line VL1 receiving the first driving voltage ELVDD and the light emitting element ED. The first transistor T1 includes a first electrode connected to the first driving voltage line VL1 via the fifth transistor T5, a second electrode connected to a pixel electrode (also referred to as anode) of the light emitting element ED via the sixth transistor T6, and a third electrode (e.g., a gate electrode) connected to one end (e.g., a first node N1) of a first capacitor Cst. The first transistor T1 may receive the i-th data signal Di received from the i-th data line DLi according to the switching operation of the second transistor T2 and supply a driving current to the light emitting element ED.

The second transistor T2 is connected between the data line DLi and the first electrode of the first transistor T1. The second transistor T2 includes a first electrode connected to the data line DLi, a second electrode connected to the first electrode of the first transistor T1, and a third electrode (e.g., a gate electrode) connected to the j-th write scan line GWLj. The second transistor T2 may be turned on according to the write scan signal GWj received through the j-th write scan line GWLj to transmit the i-th data signal Di received through the i-th data line DLi to the first electrode of the first transistor T1. One end of a second capacitor Cbst may be connected to the third electrode of the second transistor T2, and the other end of the second capacitor Cbst may be connected to the first node N1.

The third transistor T3 is connected between the second electrode of the first transistor T1 and the first node N1. The third transistor T3 includes a first electrode connected to the third electrode of the first transistor T1, a second electrode connected to the second electrode of the first transistor T1, and a third electrode (e.g., a gate electrode) connected to the j-th compensation scan line GCLj. The third transistor T3 may be turned on according to the j-th compensation scan signal GCj received through the j-th compensation scan line GCLj to connect the third electrode of the first transistor T1 and the second electrode of the first transistor T1, thereby connecting the first transistor T1 with a diode. One end of a third capacitor Nbst may be connected to the third electrode of the third transistor T3, and the other end of the third capacitor Nbst may be connected to the first node N1.

The fourth transistor T4 is connected between the first initialization voltage line VL3 to which the first initialization voltage VINT is applied and the first node N1. The fourth transistor T4 includes a first electrode connected to the first initialization voltage line VL3 to which the first initialization voltage VINT is applied, a second electrode connected to the first node N1, and a third electrode (e.g., a gate electrode) connected to the j-th initialization scan line GILj. The fourth transistor T4 is turned on according to the j-th initialization scan signal GIj received through the j-th initialization scan line GILj. The turned-on fourth transistor T4 delivers the first initialization voltage VINT to the first node N1 to initialize the potential of the third electrode (i.e., the potential of the first node N1) of the first transistor T1.

The fifth transistor T5 includes a first electrode connected to the first driving voltage line VL1, a second electrode connected to the first electrode of the first transistor T1, and a third electrode (e.g., a gate electrode) connected to the j-th light emitting control line ECLj. The sixth transistor T6 includes a first electrode connected to the second electrode of the first transistor T1, a second electrode connected to a pixel electrode of the light emitting element ED, and a third electrode (e.g., a gate electrode) connected to the j-th light emitting control line ECLj.

The fifth and sixth transistors T5 and T6 are turned on together according to the j-th light emitting control signal EMj received through the j-th light emitting control line ECLj. The first driving voltage ELVDD applied through the turned-on fifth transistor T5 may be compensated through the diode-connected first transistor T1 and then delivered to the light emitting element ED through the sixth transistor T6.

The seventh transistor T7 includes a first electrode connected to the second initialization voltage line VL4 to which the second initialization voltage VAINT is delivered, a second electrode connected to the second electrode of the sixth transistor T6, and a third electrode (e.g., a gate electrode) connected to the j-th black scan line GBLj. The second initialization voltage VAINT may have a voltage level equal to or lower than the first initialization voltage VINT.

One end of the first capacitor Cst may be connected to the third electrode of the first transistor T1, and the other end of the first capacitor Cst may be connected to the first driving voltage line VL1. A cathode of the light emitting element ED may be connected to the second driving voltage line VL2 that delivers the second driving voltage ELVSS. The second driving voltage ELVSS may have a lower voltage level than the first driving voltage ELVDD.

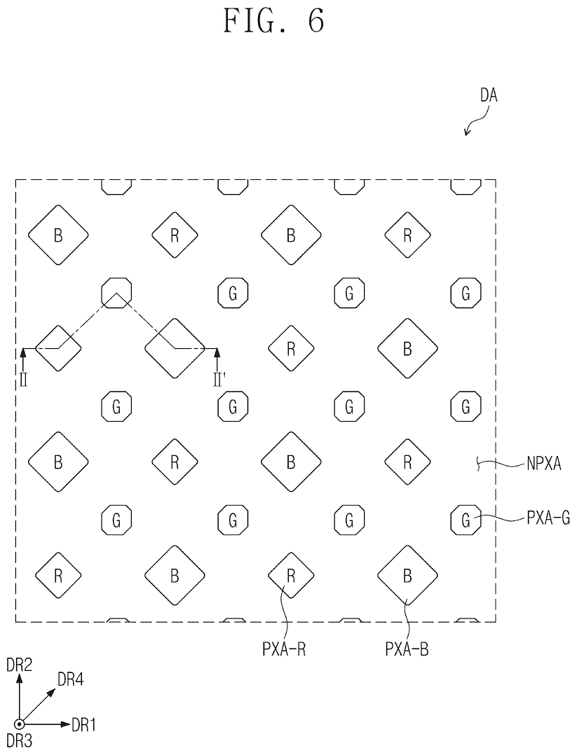

FIG. 6 is a plan view of an enlarged portion of a display region of a display panel according to one or more embodiments of the present disclosure. FIG. 6 shows a plane of (e.g., is a plan view of) a display module DM when viewed on the display surface IS (see FIG. 2) of the display module DM (see FIG. 2), and shows the arrangement of light emitting regions PXA-R, PXA-G, and PXA-B.

Referring to FIG. 6, the display region DA may include first to third light emitting regions PXA-R, PXA-G, and PXA-B and a peripheral region NPXA around (e.g., surrounding) the first to third light emitting regions PXA-R, PXA-G, and PXA-B. The first to third light emitting regions PXA-R, PXA-G, and PXA-B may each correspond to regions where light provided from light emitting elements is emitted. The first to third light emitting regions PXA-R, PXA-G, and PXA-B may be distinguished according to the color of light emitted toward the outside of the display module DM (see FIG. 2).

The first to third light emitting regions PXA-R, PXA-G, and PXA-B may provide first to third color light each having different colors. For example, the first color light may be red light, the second color light may be green light, and the third color light may be blue light. However, examples of the first to third color light are not necessarily limited to the herein-described examples.

The first to third light emitting regions PXA-R, PXA-G, and PXA-B may each be defined as a region in which an upper surface of the anode is exposed by a light emitting opening, which is described in more detail elsewhere herein. The peripheral region NPXA may set a boundary among the light emitting regions PXA-R, PXA-G, and PXA-B, and prevent or reduce the first to third light emitting regions PXA-R, PXA-G, and PXA-B from being color-mixed.

Each of the first to third light emitting regions PXA-R, PXA-G, and PXA-B may be provided in plurality and repeatedly arranged in a set or predetermined arrangement form (e.g., grouping) in the display region DA. For example, the first and third light emitting regions PXA-R and PXA-B may be alternately arranged along the first direction DR1 to form a ‘first group’. The second light emitting regions PXA-G may be arranged along the first direction DR1 to form a ‘second group’. The ‘first group’ and the ‘second group’ may each be provided in plurality, and the ‘first groups’ and ‘second groups’ may be alternately arranged along the second direction DR2.

One second light emitting region PXA-G may be provided to be spaced and/or apart from one first light emitting region PXA-R or one third light emitting region PXA-B in a fourth direction DR4. The fourth direction DR4 may be defined as a direction between the first direction DR1 and the second direction DR2.

In one or more embodiments, FIG. 6 shows an arrangement form of the first to third light emitting regions PXA-R, PXA-G, and PXA-B as an example, but the arrangement form is not limited thereto and the first to third light emitting regions PXA-R, PXA-G, and PXA-B may be arranged in one or more suitable forms. In one or more embodiments, the first to third light emitting regions PXA-R, PXA-G, and PXA-B may have an arrangement form of pentile (PENTILE™) as shown in FIG. 6. In one or more embodiments, the first to third light emitting regions PXA-R, PXA-G, and PXA-B may have an arrangement form of stripe or diamond (Diamond Pixel™), (PENTILE™ and Diamond Pixel™ are registered trademarks owned by Samsung Display Co., Ltd.).

The first to third light emitting regions PXA-R, PXA-G, and PXA-B may have one or more suitable shapes when viewed on a plane. For example, the first to third light emitting regions PXA-R, PXA-G, and PXA-B may have shapes such as a polygonal shape, a circular shape, or an elliptical shape. FIG. 6 shows first and third light emitting regions PXA-R and PXA-B having a quadrangular shape (or rhombus shape) and a second light emitting region PXA-G having an octagonal shape when viewed on a plane.

The first to third light emitting regions PXA-R, PXA-G, and PXA-B may have the same shape when viewed on a plane, or at least some of the first to third light emitting regions PXA-R, PXA-G, and PXA-B may have different shapes. FIG. 6 shows first and third light emitting regions PXA-R and PXA-B having the same shape when viewed on a plane and a second light emitting region PXA-G having a different shape from the first and third light emitting regions PXA-R and PXA-B as an example.

At least some of the first to third light emitting regions PXA-R, PXA-G, and PXA-B may have different size areas when viewed on a plane. In one or more embodiments, an area of the first light emitting region PXA-R emitting red light may be larger than an area of the second light emitting region PXA-G emitting green light, and may be smaller than an area of the third light emitting region PXA-B emitting blue light. However, the size relationship of the areas among the first to third light emitting regions PXA-R, PXA-G, and PXA-B according to the color of emitted light is not limited thereto, and may vary depending on the design of the display module DM (see FIG. 2). In one or more embodiments, the embodiment of the present disclosure is not limited thereto, and the first to third light emitting regions PXA-R, PXA-G, and PXA-B may have the same size area when viewed on a plane.

In one or more embodiments, the shape, area, and arrangement of the first to third light emitting regions PXA-R, PXA-G, and PXA-B of the display module DM (see FIG. 2) according to one or more embodiments of the present disclosure may be designed in one or more suitable ways according to the color of emitted light or the size and configuration of the display module DM (see FIG. 2), and this is not limited to the embodiment shown in FIG. 6.

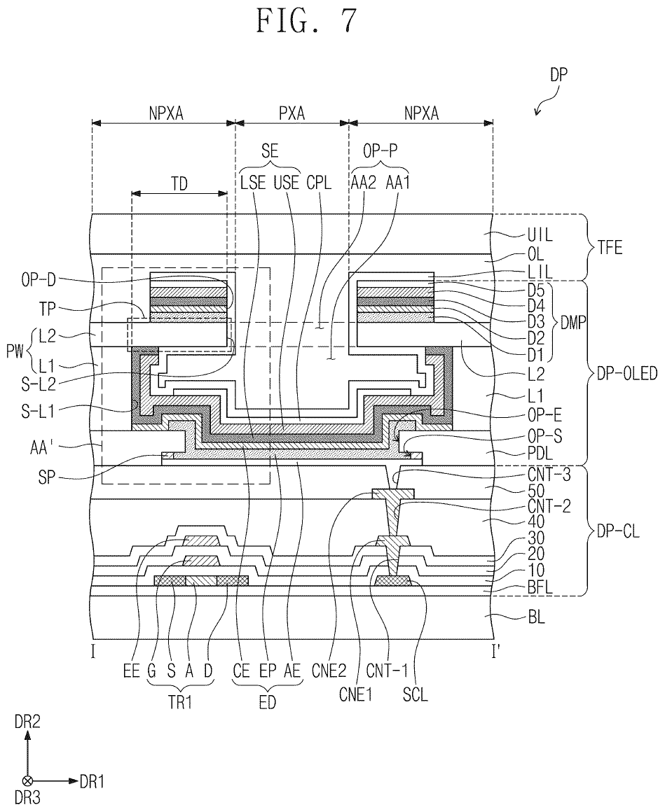

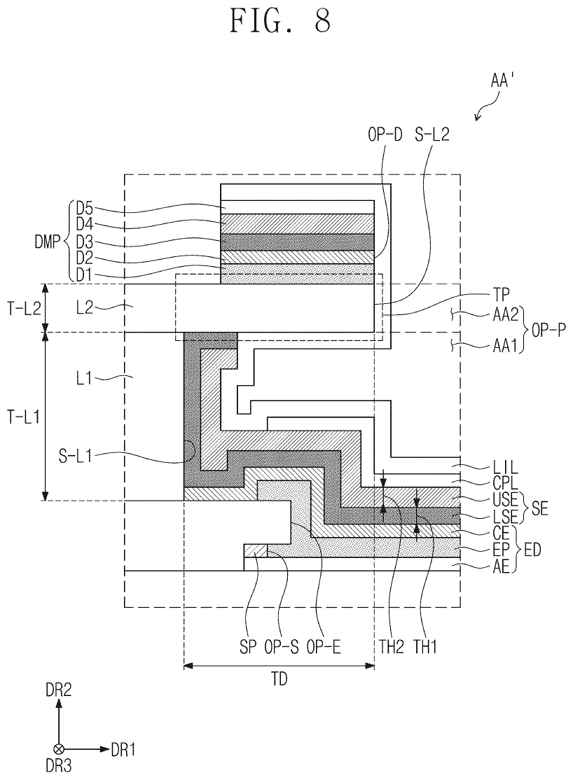

FIG. 7 is a cross-sectional view of a display panel taken along line I-I′ of FIG. 4 according to one or more embodiments of the present disclosure. FIG. 8 is a view enlarging region AA′ of FIG. 7 according to one or more embodiments of the present disclosure. FIGS. 7 and 8 will be described with reference to FIG. 3, and descriptions of the same reference numerals will not be given.

FIG. 7 is a view enlarging one light emitting region PXA in the display region DA (see FIG. 6), and the light emitting region PXA of FIG. 7 may correspond to any one among the first to third light emitting regions PXA-R, PXA-G, and PXA-B of FIG. 6. Referring to FIG. 7, the display panel DP may include a base layer BL, a circuit element layer DP-CL, a display element layer DP-OLED, and a thin film encapsulation layer TFE.

Referring to FIGS. 7 and 8, the display panel DP may include a plurality of insulating layers, semiconductor patterns, conductive patterns, signal lines, and/or the like. An insulating layer, a semiconductor layer, and a conductive layer may be formed through processes such as coating or deposition. Thereafter, the insulating layer, the semiconductor layer, and the conductive layer may be selectively patterned through photolithography and etching. The semiconductor patterns, conductive patterns, signal lines, and/or the like included in the circuit element layer DP-CL and the display element layer DP-OLED may be formed through such processes described herein.

The circuit element layer DP-CL may be provided on the base layer BL. The circuit element layer DP-CL may include a buffer layer BFL, a transistor TR1, a signal transmission region SCL, first to fifth insulating layers 10, 20, 30, 40, and 50, an electrode EE, and a plurality of connection electrodes CNE1 and/or CNE2.

The buffer layer BFL may be provided on the base layer BL. The buffer layer BFL may improve the bonding force between the base layer BL and the semiconductor patterns. The buffer layer BFL may include a silicon oxide layer and/or a silicon nitride layer. The silicon oxide layer and the silicon nitride layer may be alternately stacked.

The semiconductor patterns may be provided on the buffer layer BFL. The semiconductor patterns may include polysilicon. However, the embodiment of the present disclosure is not limited thereto, and the semiconductor patterns may include amorphous silicon or a metal oxide. FIG. 7 only shows a portion of the semiconductor patterns as an example, and the semiconductor patterns may be further provided in the plurality of light emitting regions PXA-R, PXA-G, and PXA-B (see FIG. 6). The semiconductor patterns may be arranged according to certain rules over the plurality of light emitting regions PXA-R, PXA-G, and PXA-B. The semiconductor patterns may have different electrical properties according to with or without doping. The semiconductor patterns may include a first region having a high doping concentration and a second region having a low doping concentration. The first region may be doped with an N-type or kind dopant or a P-type or kind dopant. A P-type or kind transistor may include the first region doped with the P-type or kind dopant.

The first region may have greater conductivity than the second region, and may substantially serve as an electrode or a signal line. The second region may substantially correspond to an active (or a channel) of the transistor. For example, a portion of the semiconductor patterns may be an active of the transistor, another portion may be a source or a drain of the transistor, and the other portion may be a conductive region.

A source S, an active A, and a drain D of the transistor TR may be formed from the semiconductor patterns. FIG. 7 shows a portion of the signal transmission region SCL formed from the semiconductor patterns. In one or more embodiments, the signal transmission region SCL may be connected to the drain DR of the transistor TR1 when viewed on a plane.

The first to fifth insulating layers 10, 20, 30, 40, and 50 may be provided on the buffer layer BFL. The first to fifth insulating layers 10, 20, 30, 40, and 50 may be inorganic layers and/or organic layers.

A first insulating layer 10 may be provided on the buffer layer BFL. The first insulating layer 10 may cover the source S, the active A, the drain D, and the signal transfer region SCL of the transistor TR1 provided on the buffer layer BFL. A gate G of the transistor TR1 may be provided on the first insulating layer 10. The second insulating layer 20 may be provided on the first insulating layer 10 to cover the gate G. The electrode EE may be provided on the second insulating layer 20. The third insulating layer 30 may be provided on the second insulating layer 20 to cover the electrode EE.

A first connection electrode CNE1 may be provided on the third insulating layer 30. The first connection electrode CNE1 may be connected to the signal transmission region SCL through a contact hole CNT-1 that passes through the first to third insulating layers 10, 20, and 30. The fourth insulating layer 40 may be provided on the third insulating layer 30 to cover the first connection electrode CNE1. The fourth insulating layer 40 may be an organic layer.

A second connection electrode CNE2 may be provided on the fourth insulating layer 40. The second connection electrode CNE2 may be connected to the first connection electrode CNE1 through a contact hole CNT-2 that passes through the fourth insulating layer 40. The fifth insulating layer 50 may be provided on the fourth insulating layer 40 to cover the second connection electrode CNE2. The fifth insulating layer 50 may be an organic layer.

The display element layer DP-OLED may be provided on the circuit element layer DP-CL. The display element layer DP-OLED may include a light emitting element ED, a sacrificial pattern SP, a pixel defining film PDL, a barrier rib PW, an auxiliary electrode SE, and dummy patterns DMP.

The light emitting element ED may include an anode AE (or a first electrode), a light emitting pattern EP (or an intermediate layer), and a cathode CE (or a second electrode).

The anode AE may be provided on the fifth insulating layer 50 of the circuit element layer DP-CL. The anode AE may be a transmissive electrode, a transflective electrode, or a reflective electrode. The anode AE may be connected to the second connection electrode CNE2 through a connection contact hole CNT-3 defined through the fifth insulating layer 50. Accordingly, the anode AE may be electrically connected to the signal transmission region SCL through the first and/or second connection electrodes CNE1 and CNE2 and electrically connected to a corresponding circuit element. The anode AE may include a single-layer structure or a multi-layer structure. The anode AE may include a plurality of layers including ITO and Ag. For example, the anode AE may include a layer containing ITO (hereinafter referred to as lower ITO layer), a layer containing Ag provided on the lower ITO layer (hereinafter referred to as Ag layer), and a layer containing ITO provided on the Ag layer (hereinafter referred to as upper ITO layer).

The sacrificial pattern SP may be provided between the anode AE and the pixel defining film PDL. A sacrificial opening OP-S exposing a portion of the upper surface of the anode AE may be defined in the sacrificial pattern SP. The sacrificial opening OP-S may overlap a light emitting opening OP-E, which will be described later.

The pixel defining film PDL may be provided on the base layer BL. To be more specific, the pixel defining film PDL may be provided on the fifth insulating layer 50 of the circuit element layer DP-CL. A light emitting opening OP-E may be defined in the pixel defining film PDL. The light emitting opening OP-E may correspond to the anode AE, and the pixel defining film PDL may expose at least a portion of the anode AE through the light emitting opening OP-E.

In one or more embodiments, the light emitting opening OP-E may correspond to the sacrificial opening OP-S of the sacrificial pattern SP. According to one or more embodiments of the present disclosure, the upper surface of the anode AE may be spaced and/or apart from the pixel defining film PDL in a cross-section with the sacrificial pattern SP therebetween, and accordingly, the anode AE may be protected from being damaged in a process of forming (e.g., providing or applying) the light emitting opening OP-E.

When viewed on a plane (e.g., in a plan view), an area of the light emitting opening OP-E may be smaller than an area of the sacrificial opening OP-S. For example, an inner surface of the pixel defining film PDL defining the light emitting opening OP-E may be closer to the center of the anode AE than an inner surface of the sacrificial pattern SP defining the sacrificial opening OP-S. However, the embodiment of the present disclosure is not limited thereto, and the inner surface of the sacrificial pattern SP defining the sacrificial opening OP-S may be substantially aligned with the inner surface of the pixel defining film PDL defining the light emitting opening OP-E.

The pixel defining film PDL may include an inorganic insulating material. For example, the pixel defining film PDL may include silicon nitride (SiNx). The pixel defining film PDL may be provided between the anode AE and the barrier rib PW to prevent or reduce the anode AE and the barrier rib PW from being electrically connected.

The barrier rib PW may be provided on the pixel defining film PDL. A barrier rib opening OP-P may be defined in the barrier rib PW. The barrier rib opening OP-P may overlap the light emitting opening OP-E and may expose at least a portion of the anode AE.

The barrier rib PW may have an undercut shape in a cross-section. The barrier rib PW may include a plurality of layers which are sequentially stacked, and at least one layer of the plurality of layers may be recessed compared to other layers. Accordingly, the barrier rib PW may include a tip portion TP.

The barrier rib PW may include a first barrier rib layer L1 and a second barrier rib layer L2. The first barrier rib layer L1 may be provided on the pixel defining film PDL, and the second barrier rib layer L2 may be provided on the first barrier rib layer L1. As shown in FIG. 7, the first barrier rib layer L1 may have a greater thickness than the second barrier rib layer L2, but the embodiment of the present disclosure is not limited thereto.

The first barrier rib layer L1 may be relatively recessed compared to the second barrier rib layer L2 with respect to the light emitting region PXA. The first barrier rib layer L1 may be formed to have an undercut with respect to the second barrier rib layer L2. A portion of the second barrier rib layer L2, which is protruding from the first barrier rib layer L1 toward the light emitting region PXA may define the tip portion TP in the barrier rib PW. For example, the second barrier rib layer L2 may include a tip portion TP protruding from the first barrier rib layer L1 toward the barrier rib opening OP-P.

A length TD of the tip portion TP in the first direction DR1 may be a length from the first inner surface S-L1 of the first barrier rib layer L1 overlapping the pixel defining film PDL to the second inner surface S-L2 of the second barrier rib layer L2

The barrier rib opening OP-P defined in the barrier rib PW may include a first portion AA1 and a second portion AA2. The first barrier rib layer L1 may include a first inner surface S-L1 defining the first region AA1 of the barrier rib opening OP-P, and the second barrier rib layer L2 may include a second inner surface S-L2 defining the second region AA2. In a cross-section, the second inner surface S-L2 of the second barrier rib layer L2 may be closer to the center of the anode AE than the first inner surface S-L1 of the first barrier rib layer L1. The first inner surface S-L1 may be recessed in a direction farther from the center of the anode AE than the second inner surface S-L2.

A width of the first region AA1 and a width of the second region AA2 may be different. The first region AA1 may have a greater width than the second region AA2. In this case, the second region AA2 of the barrier rib opening OP-P may be a region defining the tip portion TP.

The first barrier rib layer L1 and the second barrier rib layer L2 may each include a conductive material. For example, the conductive material may include metal, transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

FIG. 7 shows that each of the first and second inner surfaces S-L1 and S-L2 is perpendicular to an upper surface of the pixel defining film PDL, but the embodiment of the present disclosure is not limited thereto. For example, the barrier rib PW may have a tapered shape or an inverse taper shape.

The light emitting pattern EP may be provided on the anode AE to emit light. The light emitting pattern EP may include an emission layer including a light emitting material. The light emitting pattern EP may further include a hole injection layer (HIL) and a hole transport layer (HTL) provided between the anode AE and the emission layer, and may further include an electron transport layer (ETL) and an electron injection layer (EIL) provided on the emission layer. The light emitting pattern EP may also be referred to as an ‘organic layer’ or an ‘intermediate layer’.

The light emitting pattern EP may be patterned by the tip portion TP defined in the barrier rib PW. The light emitting pattern EP may be provided inside the sacrificial opening OP-S, the light emitting opening OP-E, and/or the barrier rib opening OP-P. A portion of the upper surface of the pixel defining film PDL exposed from the barrier rib opening OP-P may be deposited with the light emitting pattern EP. For example, both (e.g., simultaneously) ends of the light emitting pattern EP may be formed on the upper surface of the pixel defining film PDL. The light emitting pattern EP may be spaced and/or apart from the side of the barrier rib PW when viewed on a plane. For example, the light emitting pattern EP may be spaced and/or apart from the first inner surface S-L1 of the first barrier rib layer L1 when viewed on a plane. For example, the light emitting pattern EP may not contact the barrier rib PW.

Among the hole injection layers included in the light emitting pattern EP, a p-doped hole injection layer may have conductivity. In this case, when the light emitting pattern EP is formed in contact with the barrier rib PW, the barrier rib PW containing a conductive material and the light emitting pattern EP may be electrically connected, resulting in leakage current. According to one or more embodiments of the present disclosure, as the light emitting pattern EP is spaced and/or apart from the barrier rib PW when viewed on a plane, the leakage current may be prevented or reduced from taking place, e.g., even when a portion of the light emitting pattern EP (e.g., the p-doped hole injection layer) is conductive.

The cathode CE may be provided on the light emitting pattern EP. The cathode CE may be patterned by the tip portion defined in the barrier rib PW. At least a portion of the cathode CE may be provided in the barrier rib opening OP-P. The upper surface of the pixel defining film PDL exposed from the barrier rib opening OP-P may be deposited with the cathode CE. For example, both (e.g., simultaneously) ends of the cathode CE may be formed on the pixel defining film PDL.

Both ends of the cathode CE may be electrically connected by contacting the side of the barrier rib PW. However, in FIG. 7, the cathode CE is shown to be in contact with the side of the barrier rib PW as an example, but the embodiment of the present disclosure is not limited thereto. For example, both (e.g., simultaneously) ends of the cathode CE may be possibly spaced and/or apart from the side of the barrier rib PW when viewed on a plane. For example, the cathode CE may be spaced and/or apart from the first inner surface S-L1 of the first barrier rib layer L1 when viewed on a plane (e.g., in a plan view). In this case, the cathode CE may be electrically connected to the barrier rib PW through the auxiliary electrode SE.

The cathode CE may have conductivity. The cathode CE may be formed of one or more suitable materials as long as the materials such as metal, transparent conductive oxide (TCO), or a conductive polymer material have conductivity. For example, the cathode CE may include silver (Ag), magnesium (Mg), lead (Pu), copper (Cu), or a compound thereof.

The auxiliary electrode SE may be provided on the light emitting element ED. The auxiliary electrode SE may be provided on the cathode CE. The auxiliary electrode SE may contact the barrier rib PW and the cathode CE. For example, the auxiliary electrode SE may be electrically connected to the barrier rib PW and the cathode CE. The barrier rib PW may receive the second driving voltage ELVSS (see FIG. 5), and the auxiliary electrode SE may be electrically connected to the barrier rib PW to receive the second driving voltage ELVSS. Accordingly, the cathode CE electrically connected to the auxiliary electrode SE may receive the second driving voltage ELVSS.

The auxiliary electrode SE may contact a portion of the lower surface of the tip portion TP. The auxiliary electrode SE may not be in contact with at least a portion of the lower surface of the tip portion TP. The auxiliary electrode SE may be conductive. According to one or more embodiments of the present disclosure, the cathode CE may be electrically connected to the barrier rib PW through the auxiliary electrode SE. Adhesion between the auxiliary electrode SE and the cathode CE and adhesion between the auxiliary electrode SE and the barrier rib PW may be greater than adhesion between the cathode CE and the barrier rib PW. Accordingly, the cathode CE in contact with the barrier rib PW by the auxiliary electrode SE may be prevented or reduced from lifting, and thus foreign substances may be prevented or reduced from entering into the display element layer DP-OLED.

The auxiliary electrode SE may include a lower auxiliary electrode LSE and an upper auxiliary electrode USE. The lower auxiliary electrode LSE may contact the cathode CE and the barrier rib PW to electrically connect the cathode CE and the barrier rib PW. The lower auxiliary electrode LSE may contact the first inner surface S-L1 defining the barrier rib opening OP-P of the first barrier rib layer L1. The lower auxiliary electrode LSE may extend along the first inner surface S-L1 of the first barrier rib layer L1 and the lower surface of the second barrier rib layer L2. The lower auxiliary electrode LSE may not be in contact with at least a portion of the lower surface of the second barrier rib layer L2. The lower auxiliary electrode LSE may be arranged to be spaced and/or apart from a third dummy pattern D3 formed through the same process by the tip portion TP.

The lower auxiliary electrode LSE may include transparent conductive oxide (TCO) containing zinc. The lower auxiliary electrode LSE contains zinc, and may thus not be corroded even when the lower auxiliary electrode LSE contacts the first barrier rib layer L1. For example, galvanic corrosion caused by a potential difference between the first barrier rib layer L1 and the lower auxiliary electrode LSE may be prevented or reduced.

For example, when the first barrier rib layer L1 includes aluminum and the lower auxiliary electrode LSE includes indium tin oxide (ITO), corrosion may be caused by the standard reduction potential difference between the first barrier rib layer L1 and the lower auxiliary electrode LSE. In this case, when indium zinc tin oxide (IZTO) containing zinc is utilized as the lower auxiliary electrode LSE, the standard reduction potential is reduced due to zinc, and accordingly, the corrosion of the lower auxiliary electrode LSE may be prevented or reduced.

The lower auxiliary electrode LSE may include indium zinc tin oxide. As described herein, when indium zinc tin oxide is utilized as the lower auxiliary electrode LSE, the corrosion of the lower auxiliary electrode LSE may be prevented or reduced. The lower auxiliary electrode LSE may have a light transmittance of about 90% or greater. The light transmittance of the lower auxiliary electrode LSE may be about 90% or greater for each (e.g., any or all) of red light, green light, and/or blue light.

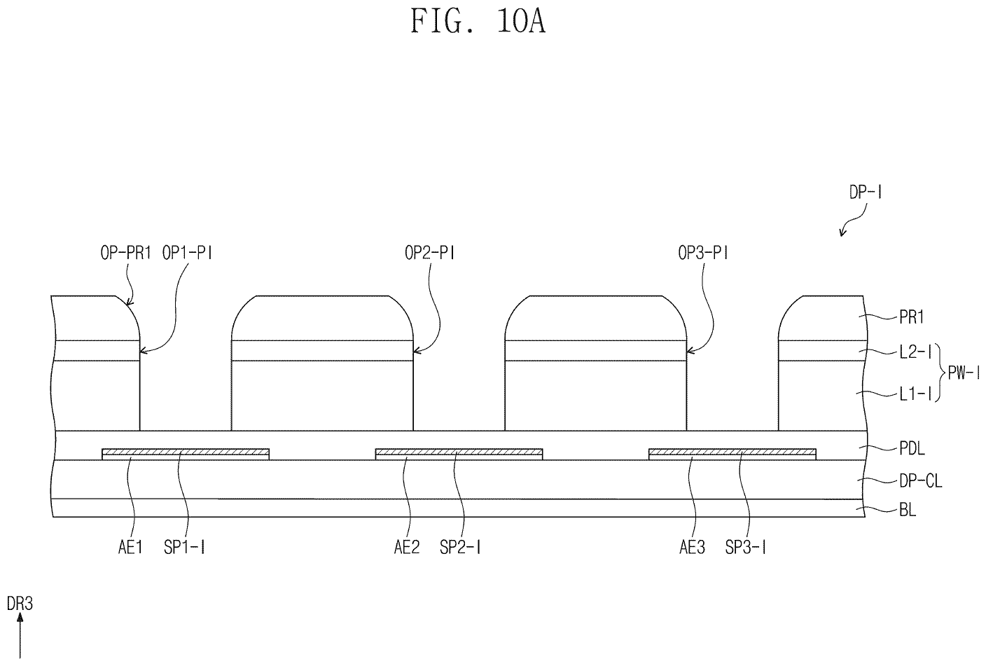

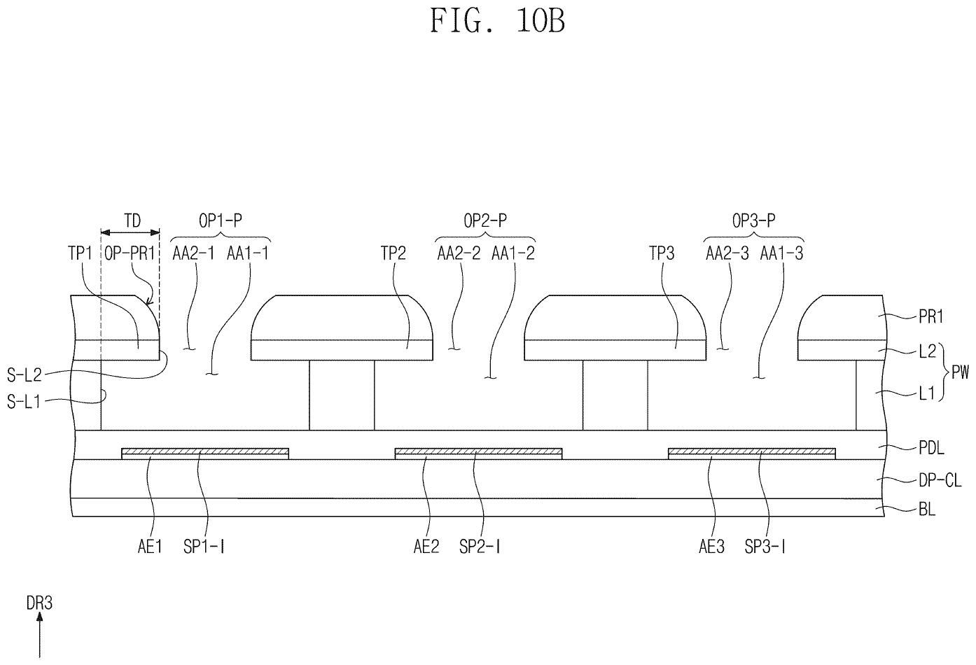

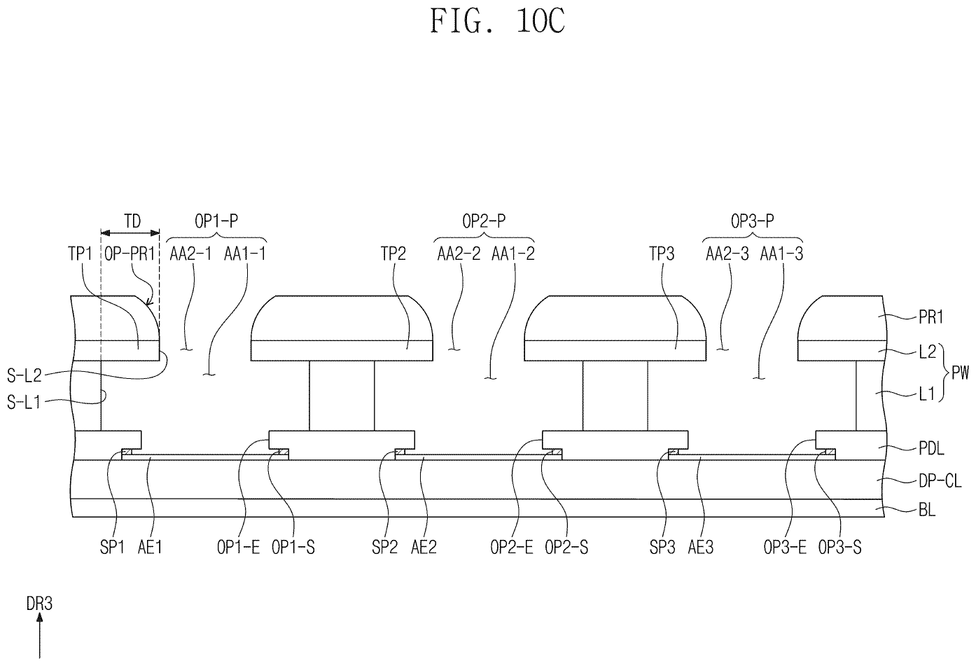

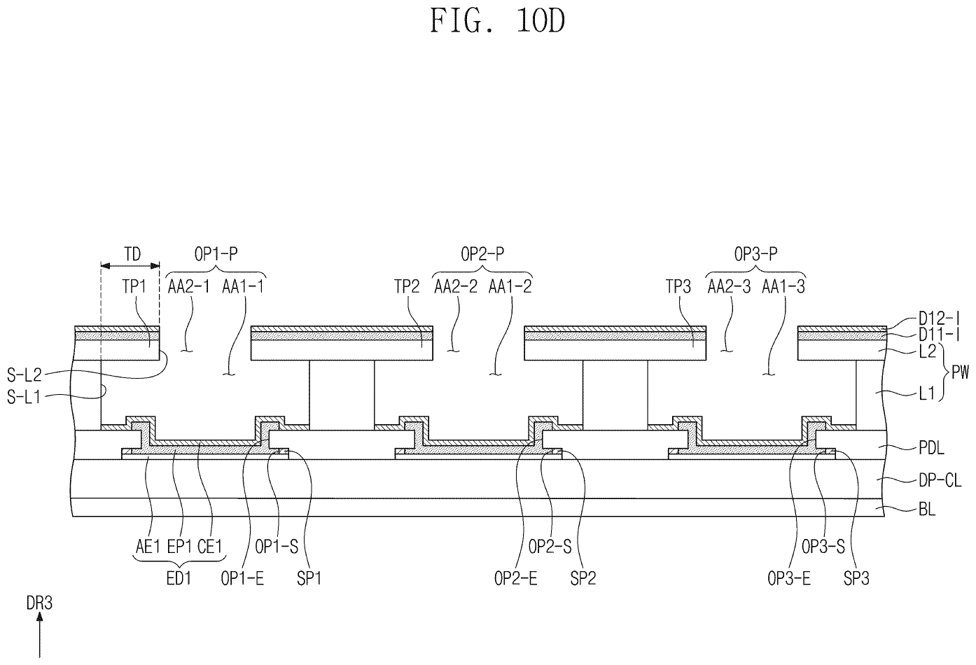

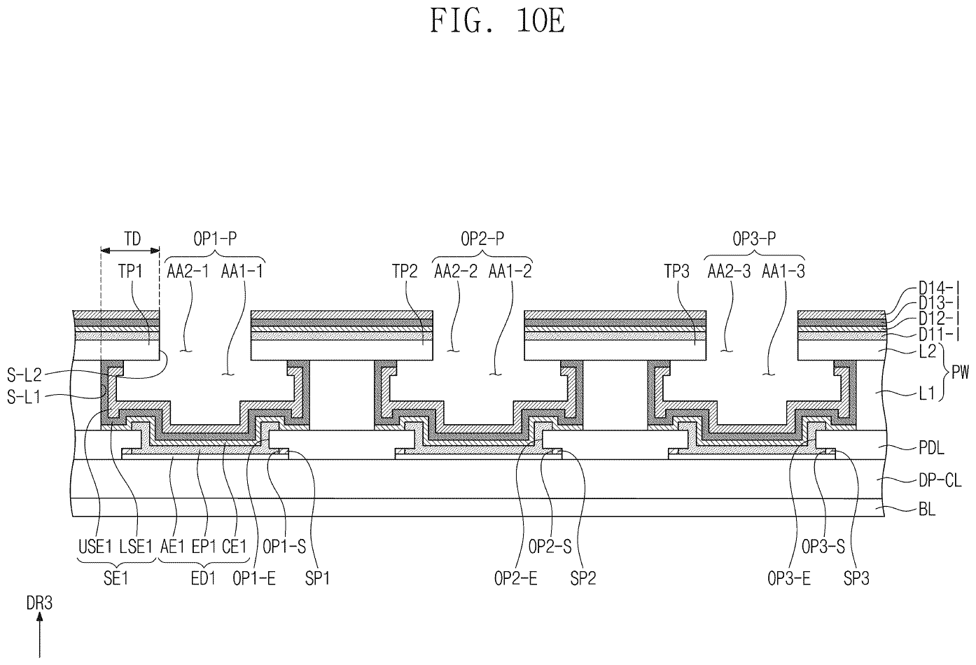

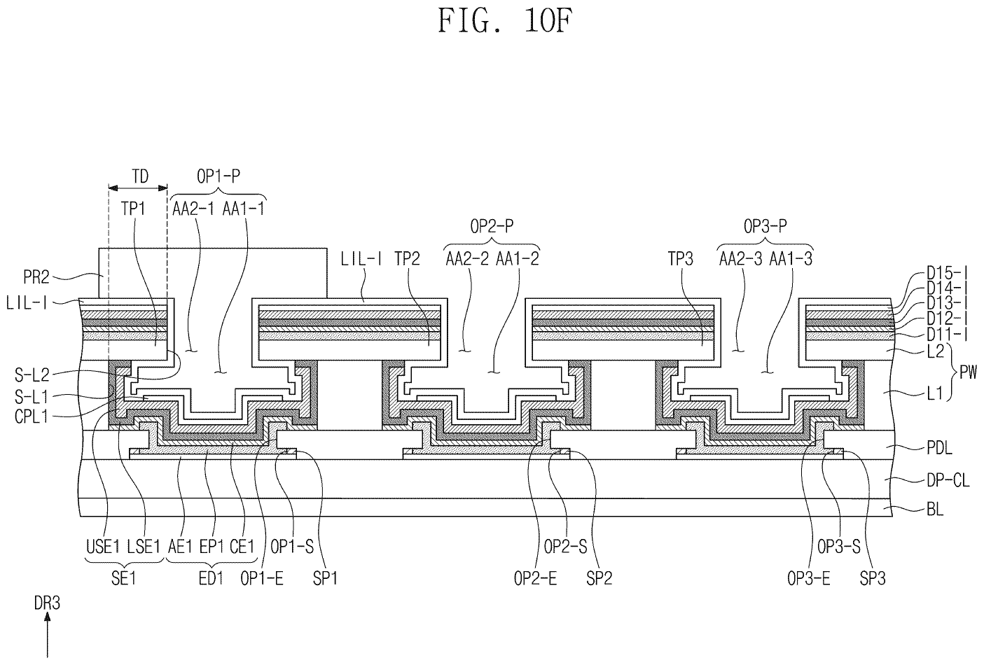

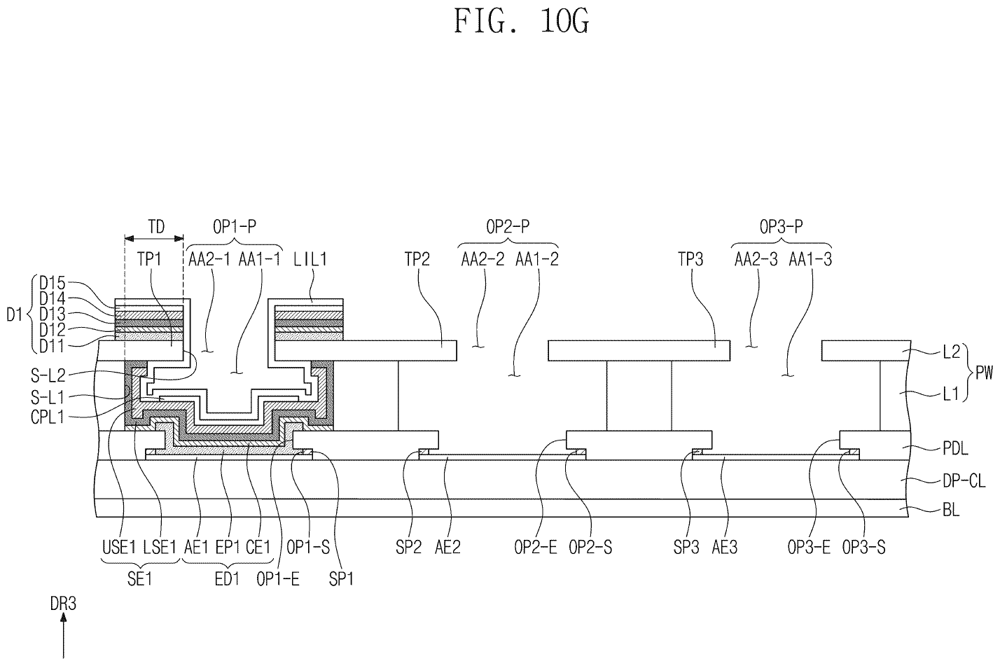

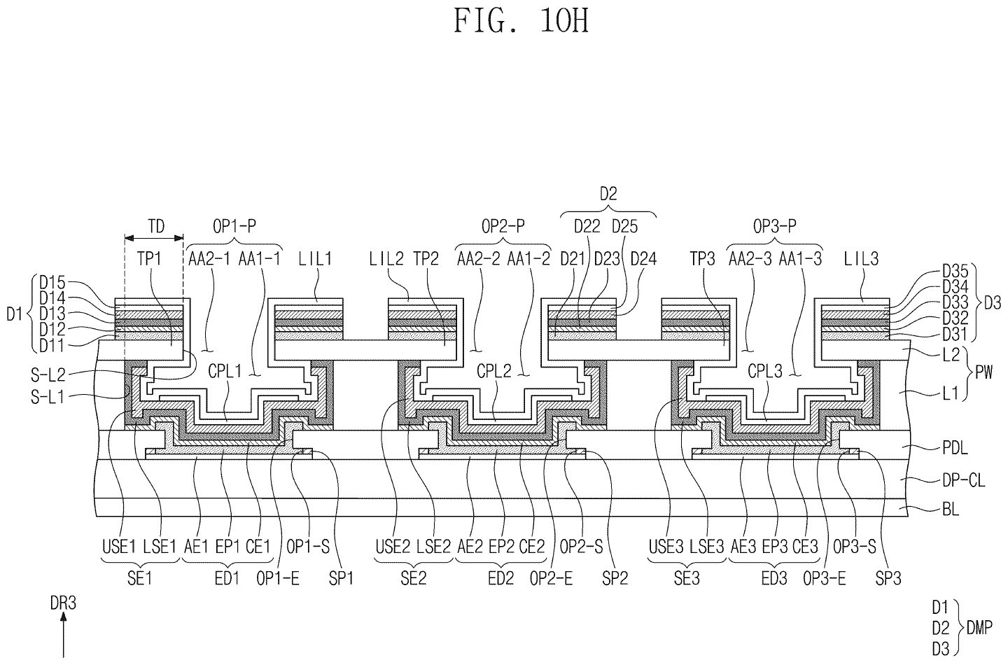

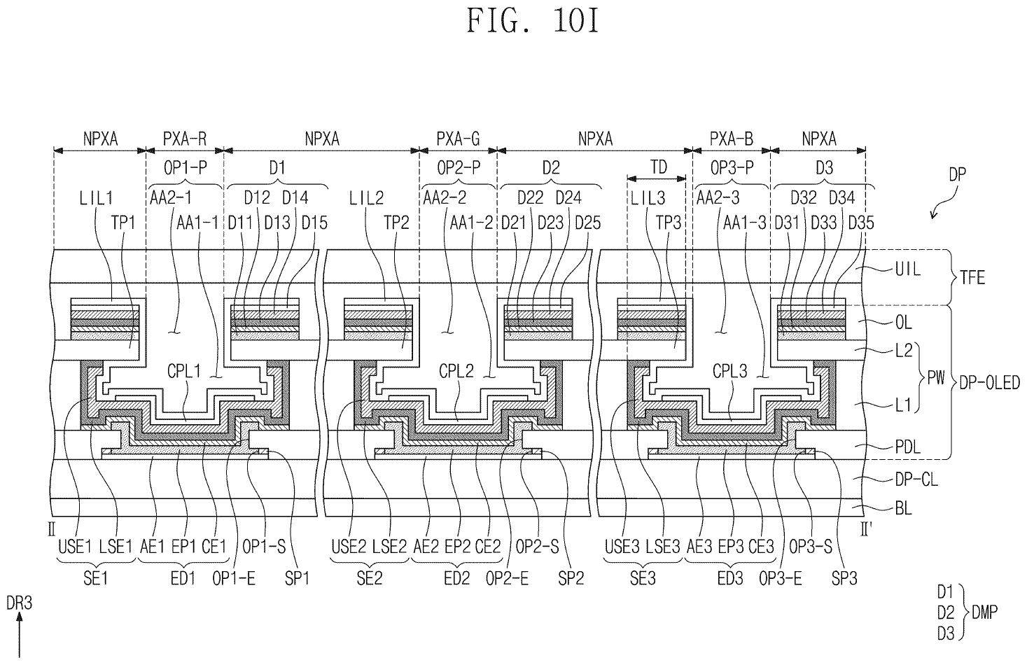

The lower auxiliary electrode LSE may have a first thickness TH1 of about 50 Å to about 200 Å. When the first thickness TH1 of the lower auxiliary electrode LSE is less than about 50 Å, it may fail to prevent or reduce the cathode CE from lifting or fail to prevent or reduce foreign substances from entering into the light emitting element ED. When the first thickness TH1 of the lower auxiliary electrode LSE is greater than about 200 Å, the lower auxiliary electrode LSE may be subjected to crystallization, making it difficult to etch the lower auxiliary electrode LSE, e.g., during a step later on in the preparation process, e.g., as described in more detail in the description of a method for manufacturing a display device with reference to FIGS. 10A to 10I. Accordingly, the lower auxiliary electrode LSE may have a first thickness TH1 of about 50 Å to about 200 Å. In one or more embodiments, the first thickness TH1 of the lower auxiliary electrode LSE may be about 150 Å.

When the lower auxiliary electrode LSE contains indium zinc tin oxide (IZTO), indium atoms and zinc atoms may substantially be in substantially the same amount, and tin atoms may be in an amount between about 14 at % to about 22 at % based on a total of 100 at % of IZTO. For example, an amount of indium atoms may be substantially the same as an amount of zinc atoms. The lower auxiliary electrode LSE may be formed of indium zinc tin oxide having the described composition, and accordingly, the lower auxiliary electrode LSE may have an amorphous crystal phase. When the lower auxiliary electrode LSE is in an amorphous state, an etching process may be easily performed in the method for manufacturing a display device, as described in more detail elsewhere herein.

The upper auxiliary electrode USE may be provided on the lower auxiliary electrode LSE and may be electrically connected to the lower auxiliary electrode LSE. Accordingly, the lower auxiliary electrode LSE, the upper auxiliary electrode USE, the cathode CE, and the first barrier rib layer L1 may be electrically connected. The upper auxiliary electrode USE may extend along the lower auxiliary electrode LSE. The upper auxiliary electrode USE may be arranged to be spaced and/or apart from a fourth dummy pattern D4 formed through the same process by the tip portion TP.

The upper auxiliary electrode USE may include transparent conductive oxide. The upper auxiliary electrode USE may include indium tin oxide. The upper auxiliary electrode USE may not be in contact with the first barrier rib layer L1. A lower auxiliary electrode LSE containing zinc and resistant to corrosion may be provided between the upper auxiliary electrode USE and the first barrier rib layer L1. By preventing or reducing direct contact between the upper auxiliary electrode USE and the first barrier rib layer L1, the upper auxiliary electrode USE may be prevented or reduced from being corroded.

For example, when the first barrier rib layer L1 contains aluminum, the upper auxiliary electrode USE includes indium tin oxide, and the first barrier rib layer L1 is in contact with the upper auxiliary electrode USE, the upper auxiliary electrode USE may be damaged by galvanic corrosion. In this case, the lower auxiliary electrode LSE containing indium zinc tin oxide may prevent or reduce damage to the upper auxiliary electrode USE by preventing or reducing contact between the upper auxiliary electrode USE and the first barrier rib layer L1.

In the indium tin oxide (ITO) of the upper auxiliary electrode USE, indium oxide (In₂O₃) may be in a weight percent of about 90 wt % and tin oxide (SnO) may be in a weight percent of about 10 wt % based on a total of 100 wt % of ITO. The upper auxiliary electrode USE is formed of indium tin oxide of this composition, the upper auxiliary electrode USE may have an amorphous crystal phase. When the upper auxiliary electrode USE has an amorphous crystal phase, an etching process may be easily performed in the method for manufacturing a display device, as described in more detail elsewhere herein.

The upper auxiliary electrode USE may have a second thickness TH2 of about 50 Å to about 200 Å. When the second thickness TH2 of the upper auxiliary electrode USE is less than about 50 Å, it may fail to prevent or reduce the cathode CE from lifting or fail to prevent or reduce foreign substances from entering into the light emitting element ED. When the second thickness TH2 of the upper auxiliary electrode USE is greater than about 200 Å, the upper auxiliary electrode USE may be subjected to crystallization, making it difficult to etch the lower auxiliary electrode LSE, e.g., during a step later on in the preparation process. In one or more embodiments, the second thickness TH2 of the upper auxiliary electrode USE may be about 150 Å.

The upper auxiliary electrode USE may have a light transmittance of about 90% or greater. The light transmittance of the upper auxiliary electrode USE may be about 90% or greater for each (e.g., any or all) of red light, green light, and blue light.

Table 1 included herein is a table showing the light transmittance of the auxiliary electrode according to the wavelength of light in Comparative Example, Example 1, and Example 2. Comparative Example is a case where indium zinc oxide (IZO) was utilized as an auxiliary electrode and the auxiliary electrode had a thickness of about 650 Å. Example 1 is a case where indium tin oxide was utilized as an auxiliary electrode and the auxiliary electrode had a thickness of about 150 Å. Example 2 is a case where indium zinc tin oxide was utilized as an auxiliary electrode and the auxiliary electrode had a thickness of about 150 Å.

TABLE 1

| Wavelength of | Comparative | | |
|---|---|---|---|
| light (nm) | Example | Example 1 | Example 2 |
| 450 | 79% | 94.04% | 95.04% |
| 550 | 81.8% | 96.62% | 97.16% |
| 650 | 85.8% | 97.9% | 98.06% |

Referring to Table 1, it is seen that the case where indium tin oxide (Example 1) or indium zinc tin oxide (Example 2) was utilized as an auxiliary electrode had greater light transmittance than the case where indium zinc oxide was utilized as an auxiliary electrode (Comparative Example). This may apply to a case where the wavelength of light is 450 nm (blue light), a case where the wavelength of light is 550 nm (green light), and/or a case where the wavelength of light is 650 nm (red light), e.g., each or all together. It is seen that the light transmittance of the auxiliary electrode was greater when the thickness of the auxiliary electrode was about 150 Å (Examples 1 and 2) than when the thickness of the auxiliary electrode was about 650 Å (Comparative Example).

In Examples 1 and 2, the light transmittance of the auxiliary electrode for blue light, green light, and red light was each (e.g., all) about 90% or greater. In Examples 1 and 2, the light transmittance of the auxiliary electrode for blue light, green light, and red light was each (e.g., all) about 94% or greater. Considering the results in Table 1, the light transmittance of the auxiliary electrode may be improved by utilizing indium tin oxide or indium zinc tin oxide as the auxiliary electrode and setting the thickness of the auxiliary electrode to about 150 Å. Accordingly, the display device may have improved luminance.

Referring to FIGS. 7 and 8, a capping pattern CPL may be provided in the barrier rib opening OP-P. The capping pattern CPL may be provided on the cathode CE or on the auxiliary electrode SE. The capping pattern CPL may be patterned by the tip portion TP formed in the barrier rib PW. The capping pattern CPL may overlap the light emitting opening OP-P.

Dummy patterns DMP may be provided on the barrier rib PW. The dummy patterns DMP may include a first dummy pattern D1, a second dummy pattern D2, a third dummy pattern D3, a fourth dummy pattern D4, and a fifth dummy pattern D5. The first to fifth dummy patterns D1, D2, D3, D4, and D5 may be sequentially stacked along the third direction DR3 on the upper surface of the second barrier rib layer L2 of the barrier rib PW.

The first dummy pattern D1 may include an organic material. For example, the first dummy pattern D1 may include the same material as the light emitting pattern EP. The first dummy pattern D1 may be formed together with the light emitting pattern EP through a single process, and separated from the light emitting pattern EP by the undercut shape of the barrier rib PW.

The second dummy pattern D2 may include a conductive material. For example, the second dummy pattern D2 may include the same material as the cathode CE. The second dummy pattern D2 may be formed together with the cathode CE through a single process and separated from the cathode CE by the undercut shape of the barrier rib PW.

The third dummy pattern D3 may include a conductive material. For example, the third dummy pattern D3 may include the same material as the lower auxiliary electrode LSE. The third dummy pattern D3 may be formed together with the lower auxiliary electrode LSE through a single process, and separated from the lower auxiliary electrode LSE by the undercut shape of the barrier rib PW.

The fourth dummy pattern D4 may include a conductive material. For example, the fourth dummy pattern D4 may include the same material as the upper auxiliary electrode USE. The fourth dummy pattern D4 may be formed together with the upper auxiliary electrode USE through a single process, and separated from the upper auxiliary electrode USE by the undercut shape of the barrier rib PW.

The fifth dummy pattern D5 may include the same material as the capping pattern CPL. The fifth dummy pattern D5 may be formed together with the capping pattern CPL through a single process, and separated from the capping pattern CPL by the undercut shape of the barrier rib PW.

A dummy opening OP-D may be defined in the dummy patterns DMP. The dummy opening OP-D may overlap the light emitting opening OP-E. When viewed on a plane, the first to fifth dummy patterns D1, D2, D3, D4, and D5 may each have a closed line shape around (e.g., surrounding) a light emitting region PXA.

FIG. 7 shows, as an example, that the inner surfaces of the first to fifth dummy patterns D1, D2, D3, D4, and D5 are aligned with the second inner surface S-L2 of the second barrier rib layer L2, but the embodiment of the present disclosure is not limited thereto, and the first to fifth dummy patterns D1, D2, D3, D4, and D5 may cover the second inner surface S-L2 of the second barrier rib layer L2.

The thin film encapsulation layer TFE may be provided on the display element layer DP-OLED. The thin film encapsulation layer TFE may include a lower encapsulation inorganic pattern LIL, an encapsulation organic film OL, and an upper encapsulation inorganic film UIL.

The lower encapsulation inorganic pattern LIL may be provided on the auxiliary electrode SE. The lower encapsulation inorganic pattern LIL may be formed to correspond to the light emitting opening OP-E. The lower encapsulation inorganic pattern LIL may be in direct contact with the upper auxiliary electrode USE. The lower encapsulation inorganic pattern LIL may contact the lower surface of the tip portion TP. A portion of the lower encapsulation inorganic pattern LIL may cover the upper auxiliary electrode USE in the barrier rib opening OP-P.

The encapsulation organic film OL may cover the lower encapsulation inorganic pattern LIL and provide a flat upper surface. The upper encapsulation inorganic film UIL may be provided on the encapsulation organic film OL.

The lower encapsulation inorganic pattern LIL and upper encapsulation inorganic film UIL may protect the display element layer DP-OLED from moisture/oxygen, and the encapsulation organic film OL may protect the display element layer DP-OLED from foreign substances such as dust particles.

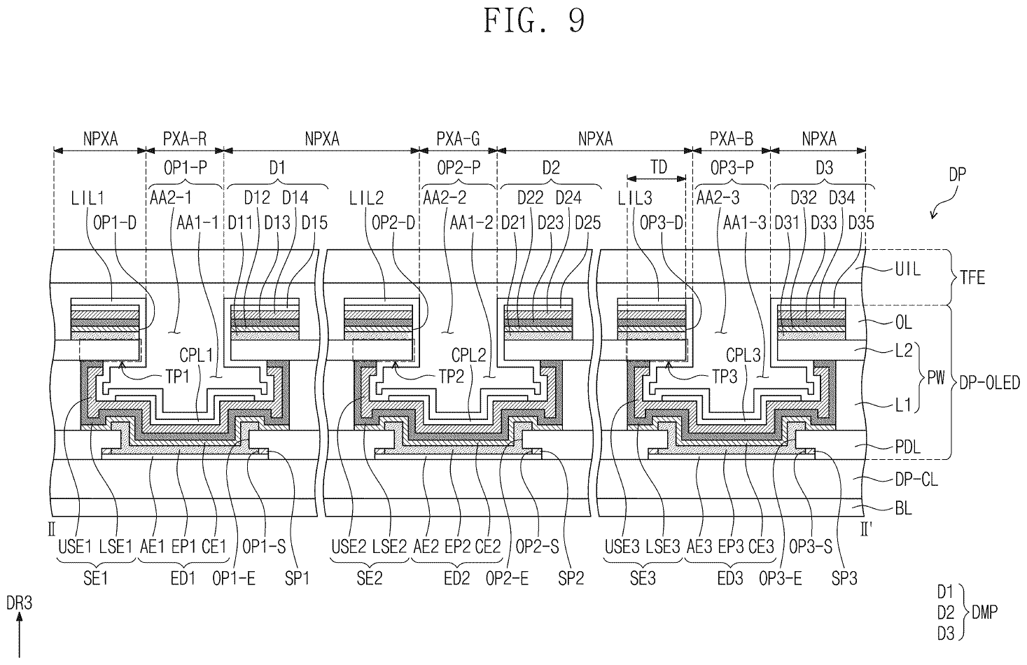

FIG. 9 is a cross-sectional view taken along line II-II′ of FIG. 6 according to one or more embodiments of the present disclosure.

FIG. 9 is a view enlarging one first light emitting region PXA-R, one second light emitting region PXA-G, and one third light emitting region PXA-B, and the description of one light emitting region PXA in FIG. 7 may equally apply to each (e.g., all) of the first to third light emitting regions PXA-R, PXA-G, and PXA-B.

Referring to FIG. 9, the display panel DP according to the present embodiment may include a base layer BL, a circuit element layer DP-CL, a display element layer DP-OLED, and a thin film encapsulation layer TFE. The display element layer DP-OLED may include light emitting elements ED1, ED2, and ED3, sacrificial patterns SP1, SP2, and SP3, a pixel defining film PDL, a barrier rib PW, auxiliary electrodes SE1, SE2, and SE3, and dummy patterns DMP.

The light emitting element ED1, ED2, and ED3 may include a first light emitting element ED1, a second light emitting element ED2, and a third light emitting element ED3. The first light emitting element ED1 may overlap a first light emitting opening OP1-E. The second light emitting element ED2 may overlap a second light emitting opening OP2-E. The third light emitting element ED3 may overlap a third light emitting opening OP3-E.

The first light emitting element ED1 may include a first anode AE1, a first light emitting pattern EP1, and a first cathode CE1. The second light emitting element ED2 may include a second anode AE2, a second light emitting pattern EP2, and a second cathode CE2. The third light emitting element ED3 may include a third anode AE3, a third light emitting pattern EP3, and a third cathode CE3. The first to third anodes AE1, AE2, and AE3 may be provided in a plurality of patterns. In one or more embodiments, the first light emitting pattern EP1 may provide red light, the second light emitting pattern EP2 may provide green light, and the third light emitting pattern EP3 may provide blue light.

In the pixel defining film PDL, the first to third light emitting openings OP1-E, OP2-E, and OP3-E may be defined. The first light emitting opening OP1-E may expose at least a portion of the first anode AE1. The second light emitting opening OP2-E may expose at least a portion of the second anode AE2. The third light emitting opening OP3-E may expose at least a portion of the third anode AE3.

The sacrificial patterns SP1, SP2, and SP3 may include a first sacrificial pattern SP1, a second sacrificial pattern SP2, and a third sacrificial pattern SP3. The first to third sacrificial patterns SP1, SP2, and SP3 may be provided on upper surfaces of the first to third anodes AE1, AE2, and AE3, respectively. In the first to third sacrificial patterns SP1, SP2, and SP3, first to third sacrificial openings OP1-S, OP2-S, and OP3-S each overlapping the first to third light emitting openings OP1-E, OP2-E, and OP3-E may be defined.

In the present embodiment, in the barrier rib PW, first to third barrier rib openings OP1-P, OP2-P, and OP3-P each overlapping the first to third light emitting openings OP1-E, OP2-E, and OP3-E may be defined. The first light emitting region PXA-R may be defined as a region exposed by the first barrier rib opening OP1-P on the upper surface of the first anode AE1. The second light emitting region PXA-G may be defined as a region exposed by the second barrier rib opening OP2-P on the upper surface of the second anode AE2. The third light emitting region PXA-B may be defined as a region exposed by the third barrier rib opening OP3-P on the upper surface of the third anode AE3.

The first to third barrier rib openings OP1-P, OP2-P, and OP3-P may each have first regions AA1-1, AA1-2, and AA1-3 corresponding to the first region AA1 (see FIG. 7), and second regions AA2-1, AA2-2, and AA2-3 corresponding to the second region AA2 (see FIG. 7), which are described herein in FIG. 7. The first barrier rib layer L1 may include first inner surfaces S-L1 (see FIG. 7) defining the first region AA1-1, AA1-2, and AA1-3 of the first to third barrier rib openings OP1-P, OP2-P, and OP3-P, and the second barrier rib layer L2 may include second inner surfaces S-L2 (see FIG. 7) defining the second regions AA2-1, AA2-2, and AA2-3 of the first to third barrier rib openings OP1-P, OP2-P, and OP3-P.

The first light emitting pattern EP1 and the first cathode CE1 may be provided in the first barrier rib opening OP1-P, the second light emitting pattern EP2 and the second cathode CE2 may be provided in the second barrier rib opening OP2-P, and the third light emitting pattern EP3 and the third cathode CE3 may be provided in the third barrier rib opening OP3-P.

In the present embodiment, the first to third light emitting patterns EP1, EP2, and EP3 and the first to third cathodes CE1, CE2, and CE3 may be physically separated by the second barrier rib layer L2 forming the tip portion and be formed in each of the light emitting openings OP1-E, OP2-E, and OP3-E and the barrier rib openings OP1-P, OP2-P, and OP3-P. The first to third light emitting patterns EP1, EP2, and EP3 may each be spaced and/or apart from the barrier rib PW when viewed on a plane. For example, the first to third light emitting patterns EP1, EP2, and EP3 may each not be in contact with the first inner surfaces S-L1 of the first barrier rib layer L1.

According to one or more embodiments of the present disclosure, the plurality of first light emitting patterns EP1 may be patterned and deposited in a pixel unit by the tip portions TP1, TP2, and TP3 defined in the barrier rib PW. For example, the first light emitting patterns EP1 may commonly be formed utilizing an open mask, but may be easily divided into pixel units by the barrier rib PW.

In one or more embodiments, when the first light emitting patterns EP1 are patterned utilizing a fine metal mask (FMM), a support spacer protruding from a conductive barrier rib is required to support the fine metal mask. In one or more embodiments, the fine metal mask is spaced and/or apart from a base surface in which patterning is performed by the height of the barrier rib and the spacer, and thus there may be limitations in obtaining high resolution. In one or more embodiments, the fine metal mask is in contact with the spacer, and thus foreign substances may remain on the spacer after the patterning process of the first light emitting patterns EP1, or the spacer may be damaged due to pressing of the fine metal mask. Accordingly, a defective display panel may be formed.

According to the present embodiment, by including the barrier rib PW, physical separation among the light emitting elements ED1, ED2, and ED3 may be easily achieved. Accordingly, current leakage or driving errors among adjacent light emitting regions PXA-R, PXA-G, and PXA-B may be prevented or reduced, and independent driving of each of the light emitting element ED1, ED2, and ED3 is achievable.

In particular, by patterning the plurality of first light emitting patterns EP1 without a mask in contact with internal components in the display region DA (see FIG. 2), defects are reduced, and accordingly, the display panel DP having improved process reliability may be provided. As patterning is doable even when a separate support spacer protruding from the barrier rib PW is not provided, areas of the light emitting regions PXA-R, PXA-G, and PXA-B may be refined, and accordingly, a display panel DP in which high resolution is highly applicable may be provided.

In one or more embodiments, when manufacturing a large-area display panel DP, process costs may be reduced by skipping the production of a large-area mask, and the process may not be affected by defects that may take place in the large-area mask, and accordingly, a display panel DP having improved process reliability may be provided. The description of the plurality of first light emitting patterns EP1 may equally apply to the plurality of second and third light emitting patterns EP2 and EP3.

The auxiliary electrodes SE1, SE2, and SE3 may include a first auxiliary electrode SE1, a second auxiliary electrode SE2, and a third auxiliary electrode SE3. The first auxiliary electrode SE1 may be provided on the first light emitting element ED1, the second auxiliary electrode SE2 may be provided on the second light emitting element ED2, and the third auxiliary electrode SE3 may be provided on the third light emitting element ED3. The first to third auxiliary electrodes SE1, SE2, and SE3 may extend along the first inner surface S-L1 (see FIG. 7) of the first barrier rib layer L1. The first to third auxiliary electrodes SE1, SE2, and SE3 may each cover both (e.g., simultaneously) ends of the first to third light emitting patterns EP1, EP2, and EP3 and both (e.g., simultaneously) ends of the first to third cathodes CE1, CE2, and CE3,

The first to third auxiliary electrodes SE1, SE2, and SE3 may be electrically connected by contacting the first barrier rib layer L1 and may thus receive a common voltage, and the first to third cathodes CE1, CE2, and CE3 may receive a common cathode voltage by contacting the first to third auxiliary electrodes SE1, SE2, and SE3.

The first auxiliary electrode SE1 may include a first lower auxiliary electrode LSE1 and a first upper auxiliary electrode USE1. The second auxiliary electrode SE2 may include a second lower auxiliary electrode LSE2 and a second upper auxiliary electrode USE2. The third auxiliary electrode SE3 may include a third lower auxiliary electrode LSE3 and a third upper auxiliary electrode USE3.

The first to third lower auxiliary electrodes LSE1, LSE2, and LSE3 may contact the first inner surface S-L1 of the first barrier rib layer L1 and may contact the first to third cathodes CE1, CE2, and CE3. For example, the first lower auxiliary electrode LSE1 may be electrically connected to the first barrier rib layer L1 and the first cathode CE1, the second lower auxiliary electrode LSE2 may be electrically connected to the first barrier rib layer L1 and the second cathode CE2, and the third lower auxiliary electrode LSE3 may be electrically connected to the first barrier rib layer L1 and the third cathode CE3.

The first to third lower auxiliary electrodes LSE1, LSE2, and LSE3 may have the same characteristics as the lower auxiliary electrodes LSE described in FIGS. 7 and 8. For example, the first to third lower auxiliary electrodes LSE1, LSE2, and LSE3 may each have a thickness of about 50 Å to about 200 Å. The first to third lower auxiliary electrodes LSE1, LSE2, and LSE3 may each include indium zinc tin oxide. The first to third lower auxiliary electrodes LSE1, LSE2, and LSE3 may each have indium atoms and zinc atoms substantially in substantially the same amount, and tin atoms in an amount between about 14 at % to about 22 at %. For example, an amount of indium atoms may be substantially the same as an amount of zinc atoms. The first to third lower auxiliary electrodes LSE1, LSE2, and LSE3 may have an amorphous crystal phase. The first to third lower auxiliary electrodes LSE1, LSE2, and LSE3 may have a light transmittance of about 90% or greater.

The first to third upper auxiliary electrodes USE1, USE2, and USE3 may not be in contact with the first barrier rib layer L1. The first to third upper auxiliary electrodes USE1, USE2, and USE3 may not be in contact with the first to third cathodes CE1, CE2, and CE3. The first to third upper auxiliary electrodes USE1, USE2, and USE3 may not be in contact with the first barrier rib layer L1, and accordingly, the first to third upper auxiliary electrodes USE1, USE2, and USE3 may be prevented or reduced from being galvanically corroded due to a potential difference with the first barrier layer L1.

The first to third upper auxiliary electrodes USE1, USE2, and USE3 may have the same characteristics as the upper auxiliary electrode USE described in FIGS. 7 and 8. For example, the first to third upper auxiliary electrodes USE1, USE2, and USE3 may each have a thickness of about 50 Å to about 200 Å. The first to third upper auxiliary electrodes USE1, USE2, and USE3 may each include indium tin oxide. The first to third lower auxiliary electrodes LSE1, LSE2, and LSE3 may each have indium oxide in a weight percent of about 90 wt % and tin oxide in a weight percent of 10 wt % based on a total of 100 wt % of the indium oxide and the tin oxide. The first to third upper auxiliary electrodes USE1, USE2, and USE3 may have an amorphous crystal phase. The first to third upper auxiliary electrodes USE1, USE2, and USE3 may have a light transmittance of about 90% or greater.

The dummy patterns DMP may include a plurality of first dummy patterns D1, a plurality of second dummy patterns D2, and a plurality of third dummy patterns D3.

The first dummy patterns D1 may include (1-1)-th to (1-5)-th dummy patterns D11, D12, D13, D14, and D15 around (e.g., surrounding) the first light emitting region PXA-R when viewed on a plane. The (1-1)-th to (1-5)-th dummy patterns D11, D12, D13, D14, and D15 may each include the same material and formed through the same process as the first light emitting pattern EP1, the first cathode CE1, the first lower auxiliary electrode LSE1, the first upper auxiliary electrode USE1, and the capping pattern CPL1.

The second dummy patterns D2 may include (2-1)-th to (2-5)-th dummy patterns D21, D22, D23, D24, and D25 around (e.g., surrounding) the second light emitting region PXA-G when viewed on a plane. The (2-1)-th to (2-5)-th dummy patterns D21, D22, D23, D24, and D25 may each include the same material and formed through the same process as the second light emitting pattern EP2, the second cathode CE2, the second lower auxiliary electrode LSE2, the second upper auxiliary electrode USE2, and the second capping pattern CPL2.

The third dummy patterns D3 may include (3-1)-th to (3-5)-th dummy patterns D31, D32, D33, D34, and D35 around (e.g., surrounding) the third light emitting region PXA-B when viewed on a plane. The (3-1)-th to (3-5)-th dummy patterns D31, D32, D33, D34, and D35 may each include the same material and formed through the same process as the third light emitting pattern EP3, the third cathode CE3, the third lower auxiliary electrode LSE3, the third upper auxiliary electrode USE3, and the third capping pattern CPL3.

In the dummy patterns DMP, first to third dummy openings OP1-D, OP2-D, and OP3-D corresponding to the first to third light emitting openings OP1-E, OP2-E, and OP3-E may be defined.

The thin film encapsulation layer TFE may include lower encapsulation inorganic patterns LIL1, LIL2, and LIL3, an encapsulation organic film OL, and an upper encapsulation inorganic film UIL. In the present embodiment, the lower encapsulation inorganic patterns LIL1, LIL2, and LIL3 may include a first lower encapsulation inorganic pattern LIL1, a second lower encapsulation inorganic pattern LIL2, and a third lower encapsulation inorganic pattern LIL3. The first to third lower encapsulation inorganic patterns LIL1, LIL2, and LIL3 may overlap the first to third light emitting openings OP1-E, OP2-E, and OP3-E, respectively.

The first lower encapsulation inorganic pattern LIL1 may cover the first auxiliary electrode SE1 and the first dummy patterns D1, and a portion of the first lower encapsulation inorganic pattern LIL1 may be provided inside the first barrier rib opening OP1-P. The second lower encapsulation inorganic pattern LIL2 may cover the second auxiliary electrode SE2 and the second dummy patterns D2, and a portion of the second lower encapsulation inorganic pattern LIL2 may be provided inside the second barrier rib opening OP2-P. The third lower encapsulation inorganic pattern LIL3 may cover the third auxiliary electrode SE3 and the third dummy patterns D3, and a portion of the third lower encapsulation inorganic pattern LIL3 may be provided inside the third barrier rib opening OP3-P. The first to third lower encapsulation inorganic patterns LIL1, LIL2, and LIL3 may be provided in the form of patterns spaced and/or apart from each other.

The encapsulation organic film OL may cover the lower encapsulation inorganic pattern LIL and provide a flat upper surface. The upper encapsulation inorganic film UIL may be provided on the encapsulation organic film OL.

FIGS. 10A to 10I are cross-sectional views each showing a portion of a method for manufacturing a display device according to one or more embodiments of the present disclosure.

Referring to FIG. 10A, a method for manufacturing a display panel according to one or more embodiments may include providing a preliminary display panel DP-I. The preliminary display panel DP-I provided in the present embodiment may include a base layer BL, a circuit element layer DP-CL, first to third anodes AE1, AE2, and AE3, first to third preliminary sacrificial patterns SP1-I, SP2-I, and SP3-I, a pixel defining film PDL, a first preliminary barrier rib layer L1-I, and a second preliminary barrier rib layer L2-1.

The circuit element layer DP-CL may be formed through a typical circuit element manufacturing process that forms an insulating layer, a semiconductor layer, and a conductive layer through methods such as coating and deposition, selectively patterns the insulating layer, the semiconductor layer, and the conductive layer through photolithography and etching processes, and then forms semiconductor patterns, conductive patterns, signal lines, and/or the like.

The first anode AE1 and the first preliminary sacrificial pattern SP1-I may be formed through substantially the same patterning process, and the second anode AE2 and the second preliminary sacrificial pattern SP2-I may be formed through substantially the same patterning process. The third anode AE3 and the third preliminary sacrificial pattern SP3-I may be formed through substantially the same patterning process. The pixel defining film PDL may be provided on the base layer BL. The pixel defining film PDL may cover each (e.g., all) of the first to third anodes AE1, AE2, and AE3 and the first to third preliminary sacrificial patterns SP1-I, SP2-I, and SP3-1.

The first preliminary barrier rib layer L1-I may be provided on the pixel defining film PDL. The first preliminary barrier rib layer L1-I may be formed through a deposition process of a conductive material. The second preliminary barrier rib layer L2-I may be provided on the first preliminary barrier rib layer L1-1. The second preliminary barrier rib layer L2-I may also be formed through a deposition process of a conductive material. In the present embodiment, the first preliminary barrier rib layer L1-I may include aluminum (Al) or molybdenum (Mo), and the second preliminary barrier rib layer L2-I may include titanium (Ti), but the materials of the first preliminary barrier rib layer L1-I and the second preliminary barrier rib layer L2-I are not limited thereto. The first preliminary barrier rib layer L1-I and the second preliminary barrier rib layer L2-I may form a preliminary barrier rib PW-I.

Thereafter, the method for manufacturing a display panel according to the present embodiment may include forming (e.g., applying or providing) a first photoresist layer PR1 on the preliminary barrier rib PW-I. The first photoresist layer PR1 may be formed by forming a preliminary photoresist layer on the preliminary barrier rib PW-I and then patterning the preliminary photoresist layer, utilizing a photo mask. Through a patterning process, a first photo opening OP-PR1 may be formed in the first photoresist layer PR1. The first photo opening OP-PR1 may overlap the first to third anodes AE1, AE2, and AE3.

Thereafter, primary etching of the first preliminary barrier rib layer L1-I and the second preliminary barrier rib layer L2-I may include utilizing the first photoresist layer PR1 as a mask and dry etching the first preliminary barrier rib layer L1-I and the second preliminary barrier rib layer L2-I to form preliminary barrier rib openings OP1-PI, OP2-PI, and OP3-PI in the preliminary barrier rib (PW-I). The preliminary barrier rib openings OP1-PI, OP2-PI, and OP3-PI may include a first preliminary barrier rib opening OP1-PI, a second preliminary barrier rib opening OP2-PI, and a third preliminary barrier rib opening OP3-PI. The first preliminary barrier rib opening OP1-PI may be formed to overlap the first anode AE1, and the second preliminary barrier rib opening OP2-PI may be formed to overlap the second anode AE2. The third preliminary barrier rib opening OP3-PI may be formed to overlap the third anode AE3.

The first dry etching process in the present embodiment may be performed in an etching environment where the etching selectivity between the first preliminary barrier rib layer L1-I and the second preliminary barrier rib layer L2-1 is substantially the same. Accordingly, an inner surface of the first preliminary barrier rib layer L1-I and an inner surface of the second preliminary barrier rib layer L2-I defining the preliminary barrier rib openings OP1-PI, OP2-PI, and OP3-PI may be substantially aligned.

Thereafter, referring to FIG. 10B, the first preliminary barrier rib layer L1-I (see FIG. 10A) and the second preliminary barrier rib layer L2-I (see FIG. 10A) may be etched to form the first barrier rib layer L1 and the second barrier rib layer L2 in which barrier openings OP1-P, OP2-P, and OP3-P are defined. The etching of the first preliminary barrier rib layer L1-I (see FIG. 10A) may include utilizing the first photoresist layer PR1 as a mask and wet etching the first preliminary barrier rib layer L1-I to form the barrier rib openings OP1-P, OP2-P, and OP3-P from the preliminary barrier rib openings OP1-PI, OP2-PI, and OP3-PI (see FIG. 10A). The barrier rib openings OP1-P, OP2-P, and OP3-P may include a first barrier rib opening OP1-P, a second barrier rib opening OP2-P, and a third barrier rib opening OP3-P. The first barrier rib opening OP1-P may be formed to overlap the first anode AE1, and the second barrier rib opening OP2-P may be formed to overlap the second anode AE2. The third barrier rib opening OP3-P may be formed to overlap the third anode AE3.

The barrier rib openings OP1-P, OP2-P, and OP3-P may each include first regions AA1-1, AA1-2, and AA1-3 and second region AA2-1, AA2-2, and AA2-3 sequentially arranged in the thickness direction (i.e., the third direction DR3). The first barrier rib layer L1 may include a first inner surface S-L1 defining the first regions AA1-1, AA1-2, and AA1-3 of the barrier rib openings OP1-P, OP2-P, and OP3-P, and the second barrier rib layer L2 may include a second inner surface S-L2 defining the second regions AA2-1, AA2-2, and AA2-3.

The forming of the first barrier rib layer L1 and the second barrier rib layer L2 may include forming tip portions TP1, TP2, and TP3 protruding from the first barrier rib layer L1 toward the barrier openings OP1-P, OP2-P, and OP3-P in the second barrier rib layer L2. The secondary wet etching process in the present embodiment may be performed in an environment where the etching selectivity between the first preliminary barrier rib layer L1-I and the second preliminary barrier rib layer L2-I (see FIG. 10A) is substantial or high. Accordingly, the inner surface of the barrier rib PW defining the barrier rib openings OP1-P, OP2-P, and OP3-P may have an undercut shape in a cross-section. For example, as an etch rate of the first barrier rib layer L1 with respect to an etching solution is greater than an etch rate of the second barrier rib layer L2, the first barrier rib layer L1 will be predominantly (e.g., mainly) etched. Accordingly, the first inner surface S-L1 of the first barrier rib layer L1 may be formed to be substantially more recessed inward than the second inner surface S-L2 of the second barrier rib layer L2. The tip portions TP1, TP2, and TP3 may be formed in the barrier rib PW by a portion of the second barrier rib layer L2 that protrudes further than the first barrier rib layer L1.

A length D-TP of the tip portions TP1, TP2, and TP3 of the second barrier rib layer L2 in the first direction DR1 may be a length from the first inner surface S-L1 of the first barrier fib layer L1 overlapping the pixel defining film PDL to the second inner surface S-L2 of the second barrier rib layer L2.

Then, referring to FIG. 10C, the method for manufacturing a display panel according to the present embodiment may include etching the pixel defining film PDL and etching the preliminary sacrificial patterns SP1-I, SP2-I, and SP3-I (see FIG. 10B). The etching process of the pixel defining film PDL may be performed utilizing a dry etching method, and the first photoresist layer PR1 and the barrier rib PW (e.g., the second barrier rib layer L2) may be utilized as a mask for etching. In the pixel defining film PDL, light emitting openings OP1-E, OP2-E, and OP3-E corresponding to the barrier rib openings OP1-P, OP2-P, and OP3-P may be formed. The light emitting openings OP1-E, OP2-E, and OP3-E may include a first light emitting opening OP1-E, a second light emitting opening OP2-E, and a third light emitting opening OP3-E.

The etching process of the preliminary sacrificial patterns SP1-I, SP2-I, and SP3-I may be performed utilizing a wet etching method, and the first photoresist layer PR1 and the barrier rib PW (e.g., the second barrier rib layer L2) may be utilized as a mask for etching. In the sacrificial patterns SP1, SP2, and SP3 formed by etching the preliminary sacrificial patterns SP1-1, SP2-I, and SP3-I, sacrificial openings OP1-S, OP2-S, and OP3-S overlapping the light emitting openings OP1-E, OP2-E, and OP3-E may be formed.

The sacrificial patterns SP1, SP2, and SP3 may include a first sacrificial pattern SP1, a second sacrificial pattern SP2, and a third sacrificial pattern SP3. A first sacrificial opening OP1-S overlapping the first light emitting opening OP1-E may be formed in the first sacrificial pattern SP1, a second sacrificial opening OP2-S overlapping the second light emitting opening OP2-E may be formed in the second sacrificial pattern SP2, and a third sacrificial opening OP3-S overlapping the third light emitting opening OP3-E may be formed in the third sacrificial pattern SP3. At least a portion of the first anode AE1 may be exposed from the first sacrificial pattern SP1 and the pixel defining film PDL by the first sacrificial opening OP1-S and the first light emitting opening OP1-E, and at least a portion of the second anode AE2 may be exposed from the second sacrificial pattern SP2 and the pixel defining film PDL by the second sacrificial opening OP2-S and the second light emitting opening OP2-E. At least a portion of the third anode AE3 may be exposed from the third sacrificial pattern SP3 and the pixel defining film PDL by the third sacrificial opening OP3-S and the third light emitting opening OP3-E.

The etching process of the sacrificial patterns SP1, SP2, and SP3 may be performed in an environment where the etching selectivity between the sacrificial patterns SP1, SP2, and SP3 and the anodes AE1, AE2, and AE3 is substantial or high, and accordingly, the anodes AE1, AE2, and AE3 may be prevented or reduced from also being etched along. For example, by providing the sacrificial patterns SP1, SP2, and SP3, (e.g., each having a higher etch rate than the anodes AE1, AE2, and AE3), between the pixel defining film PDL and the anodes AE1, AE2, and AE3, the anodes AE1, AE2, and AE3 may be prevented or reduced from also being etched along and/or damaged during the etching process.

Then, referring to FIG. 10D, a first light emitting element ED1 including a first anode AE1, a first light emitting pattern EP1, and a first cathode CE1 may be formed in the first barrier rib opening OP1-P. The first light emitting pattern EP1 and the first cathode CE1 may be formed through a thermal evaporation process.

The first light emitting pattern EP1 may be formed on the first anode AE1. In the forming of the first light emitting pattern EP1, the first light emitting pattern EP1 may be separated from a preliminary (1-1)-th dummy pattern D11-I by the first tip portion TP formed on the barrier rib PW-I. The first light emitting pattern EP1 may be provided in the first light emitting opening OP1-E and the first partition opening OP1-P. In the forming of the first light emitting pattern EP1, a preliminary (1-1)-th dummy layer D11-I spaced and/or apart from the first light emitting pattern EP1 may be formed on the barrier rib PW.

The first cathode CE1 may be formed on the first light emitting pattern EP1. The first cathode CE1 may be separated from a preliminary (1-2)-th dummy pattern D12-I by the first tip portion TP formed in the barrier rib PW. The first cathode CE1 may be provided in the first barrier rib opening OP1-P. In the forming of the first cathode CE1, a preliminary (1-2)-th dummy layer D12-I spaced and/or apart from the first cathode CE1 may be formed on the barrier rib PW.

Thereafter, referring to FIG. 10E, a first lower auxiliary electrode LSE1 contacting the first cathode CE1 and the barrier rib PW and containing indium zinc tin oxide, and a first upper auxiliary electrode USE1 provided on the first lower auxiliary electrode LSE1 and containing indium tin oxide may be formed in the first barrier rib opening OP1-P.

The first lower auxiliary electrode LSE1 may be provided on the first cathode CE1 and may cover the first cathode CE1. The first lower auxiliary electrode LSE1 may be separated from a preliminary (1-3)-th dummy pattern D13-I by the first tip portion TP formed on the barrier rib PW. The first lower auxiliary electrode LSE1 may be deposited to cover both (e.g., simultaneously) ends of the first cathode CE1. In the forming of the first lower auxiliary electrode LSE1, a preliminary (1-3)-th dummy layer D13-I spaced and/or apart from the first lower auxiliary electrode LSE1 may be formed on the barrier rib PW.

In one or more embodiments, the first lower auxiliary electrode LSE1 may be formed through a sputtering process. The first lower auxiliary electrode LSE1 may be formed to contact the first barrier rib layer L1. The first lower auxiliary electrode LSE1 may be formed to extend along the first inner surface S-L1 of the first barrier rib layer L1. The first lower auxiliary electrode LSE1 may extend along a portion of a lower surface of the first tip portion TP.

The first lower auxiliary electrode LSE1 may have a thickness of about 50 Å to about 200 Å. As the thickness of the first lower auxiliary electrode LSE1 is about 200 Å or less, the first lower auxiliary electrode LSE1 may have an amorphous crystal phase.

The first upper auxiliary electrode USE1 may be provided on the first lower auxiliary electrode LSE1. The first upper auxiliary electrode USE1 may be separated from a preliminary (1-4)-th dummy pattern D14-I by the first tip portion TP formed on the barrier rib PW. In the forming of the first upper auxiliary electrode USE1, a preliminary (1-4)th dummy layer D14-I spaced and/or apart from the first upper auxiliary electrode USE1 may be formed on the barrier rib PW.

In one or more embodiments, the first upper auxiliary electrode USE1 may be formed through a sputtering process. The first upper auxiliary electrode USE1 may be formed to extend along the first lower auxiliary electrode LSE1.

The first upper auxiliary electrode USE1 may have a thickness of about 50 Å to about 200 Å. As the thickness of the first upper auxiliary electrode USE1 is about 200 Å or less, the first upper auxiliary electrode USE1 may have an amorphous crystal phase.

Thereafter, referring to FIG. 10F, the first capacity pattern CPL1 provided on the first auxiliary electrode SE1 and in the first barrier rib opening OP1-P may be formed. In the forming of the first capacity pattern CPL1, a preliminary (1-5)-th dummy layer D15-I spaced and/or apart from the first capacity pattern CPL1 may be formed on the barrier rib PW.

Thereafter, a preliminary first lower encapsulation inorganic layer LIL1-I covering the first light emitting element ED1, the first auxiliary electrode SE1, and the first capping pattern CPL1 may be formed. The preliminary first lower encapsulation inorganic layer LIL1-I may be formed through a deposition process. In one or more embodiments, the preliminary first lower encapsulation inorganic layer LIL1-I may be formed through a chemical vapor deposition (CVD) process. The preliminary first lower encapsulation inorganic layer LIL1-I may be formed on the barrier rib PW and the first auxiliary electrode SE1.

Thereafter, a second photoresist layer PR2 may be formed. In the of forming of the second photoresist layer PR2, the second photoresist layer PR2 may be formed by forming a preliminary photoresist layer and then patterning the preliminary photoresist layer, utilizing a photo mask. Through a patterning process, the second photoresist layer PR2 may be formed in a pattern shape corresponding to the first light emitting opening OP1-E.

Thereafter, referring to FIG. 10G, the preliminary (1-1)-th to (1-5)-th dummy patterns D11-1, D12-1, D13-1, D14-I, and D15-I (see FIG. 10F) and the preliminary first lower encapsulation inorganic layer LIL1-I (see FIG. 10F) may be patterned to form a first dummy pattern D1 and a first lower encapsulation inorganic layer LIL1.

Referring to FIGS. 10F and 10G, in the patterning of the preliminary first lower encapsulation inorganic layer LIL1-1, the preliminary first lower encapsulation inorganic layer LIL1-I may be dry etched to remove a portion of the preliminary first lower encapsulation inorganic layer LIL1-I, which does not overlap (e.g., non-overlaps) the second photoresist layer PR2. The patterned first lower encapsulation inorganic layer LIL1 may overlap the first light emitting opening OP1-E.

In the patterning of the preliminary (1-5)-th dummy pattern D15-1, the preliminary (1-5)-th dummy pattern D15-I may be dry etched to remove a portion of the preliminary (1-5)-th dummy pattern D15-I which does not overlap (e.g., non-overlaps) the second photoresist layer PR2.

In the patterning of the preliminary (1-3)-th dummy pattern D13-I and the preliminary (1-4)-th dummy pattern D14-I, the preliminary (1-3)-th dummy pattern D13-1 and the preliminary (1-4)-th dummy pattern D14-I may be wet etched, utilizing a stripper to remove a portion of the preliminary (1-3)-th dummy pattern D13-I and the preliminary (1-4)-th dummy pattern D14-I, which does not overlap (e.g., non-overlaps) the second photoresist layer PR2. In this case, when the preliminary (1-3)-th dummy pattern D13-I and the preliminary (1-4)-th dummy pattern D14-I are in a crystallized state, the preliminary (1-3)-th dummy pattern D13-I and the preliminary (1-4)-th dummy pattern D14-I may not be removed by wet etching and/or stripper.

Therefore, in order to facilitate the process of etching the preliminary (1-3)-th dummy pattern D13-I and the preliminary (1-4)-th dummy pattern D14-I, the preliminary (1-3)-th dummy pattern D13-I and the preliminary (1-4)-th dummy pattern D14-I are required to have an amorphous crystal phase. When indium tin oxide and indium zinc tin oxide are utilized as the preliminary (1-3)-th dummy pattern D13-I and the preliminary (1-4)-th dummy pattern D14-I, greater thickness may result in crystallization. Therefore, the preliminary (1-3)-th dummy pattern D13-I and the preliminary (1-4)-th dummy pattern D14-I may be prevented or reduced from crystallizing and the etching process may be promoted by limiting the thickness of each of the preliminary (1-3)-th dummy pattern D13-I and the preliminary (1-4)-th dummy pattern D14-I to about 200 Å or less.

In the patterning of the preliminary (1-2)-th dummy pattern D12-I and the preliminary (1-1)-th dummy pattern D11-I, wet etching and/or stripper may be utilized. A portion of the preliminary (1-2)-th dummy pattern D12-I and the preliminary (1-1)-th dummy pattern D11-1, which does not overlap (e.g., non-overlaps) the second photoresist layer PR2 may be removed.

Thereafter, referring to FIG. 10H, a second light emitting element ED2, a second auxiliary electrode SE2, a second capping pattern CPL2, a second dummy pattern D2, and a second lower encapsulation inorganic layer LIL2 may be formed at a position corresponding to the second light emitting region PXA-G (see FIG. 10I). In this case, through a process substantially the same as the process described with reference to FIGS. 10D to 10G, the second light emitting element ED2, the second auxiliary electrode SE2, the second capping pattern CPL2, the second dummy pattern D2, and the second lower encapsulation inorganic layer LIL2 may be formed.

A third light emitting element ED3, a third auxiliary electrode SE3, a third capping pattern CPL3, a third dummy pattern CPL3, and a third lower encapsulation inorganic layer LIL3 may be formed at a position corresponding to the third light emitting region PXA-B (see FIG. 10I). In this case, through a process substantially the same as the process described with reference to FIGS. 10D to 10G, the third light emitting element ED3, the third auxiliary electrode SE3, the third capping pattern CPL3, the third dummy pattern D3, and the third lower encapsulation inorganic layer LIL3 may be formed.

Thereafter, referring to FIG. 10I, the method for manufacturing a display panel according to the present embodiment may include forming an encapsulation organic film OL and an upper encapsulation inorganic film UIL to complete the display panel DP. The encapsulation organic film OL may be formed by applying an organic material utilizing an inkjet method, but is not limited thereto. The encapsulation organic film OL provides a flat upper surface. Thereafter, the upper encapsulation inorganic film UIL may be formed through the deposition of an inorganic material. Accordingly, the display panel DP including the base layer BL, the circuit element layer DP-CL, the display element layer DP-OLED, and the thin film encapsulation layer TFE may be formed.

According to one or more embodiments of the present disclosure, an auxiliary electrode having high light transmittance may be utilized to increase light transmittance.

In one or more embodiments, the auxiliary electrode may be formed as a double layer and a lower auxiliary electrode in contact with a barrier rib may be designed to contain zinc to prevent or reduce the auxiliary electrode from corroding.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The display device, light emitting element, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the light emitting device and/or light emitting element may be formed on one integrated circuit (IC) chip or on separate IC chips. Further, the various components of the light emitting device and/or light emitting element may be implemented on a flexible printed circuit film, a tape carrier package (TCP), a printed circuit board (PCB), or formed on one substrate. Further, the various components of the device and/or element may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to a preferred embodiment of the present disclosure, it will be understood that the present disclosure should not be limited to these preferred embodiments but one or more suitable changes and modifications may be made by those skilled in the art without departing from the spirit and scope of the present disclosure. Hence, the technical scope of the present disclosure is not limited to the detailed descriptions in the specification but should be determined only with reference to the claims and equivalents thereof.

What is claimed is:

1. A display device comprising:
a base layer;
a pixel defining film on the base layer and having a light emitting opening defined therein;
a barrier rib comprising a first barrier rib layer on the pixel defining film and a second barrier rib layer on the first barrier rib layer, and having a barrier rib opening defined therein, the barrier rib opening overlapping the light emitting opening;
a light emitting element overlapping the light emitting opening, and comprising a first electrode, a light emitting pattern on the first electrode and configured to emit light, and a second electrode on the light emitting pattern; and
an auxiliary electrode on the second electrode, contacting the barrier rib,
the auxiliary electrode comprising:
a lower auxiliary electrode on the second electrode, contacting the barrier rib, and comprising indium zinc tin oxide (IZTO); and
an upper auxiliary electrode on the lower auxiliary electrode and comprising indium tin oxide (ITO).

2. The display device of claim 1, wherein the lower auxiliary electrode has a thickness between equal to or greater than about 50 angstrom (Å) and equal to or less than about 200 Å.

3. The display device of claim 1, wherein the upper auxiliary electrode has a thickness between equal to or greater than about 50 Å and equal to or less than about 200 Å.

4. The display device of claim 1, wherein the lower auxiliary electrode is on a first inner surface of the barrier rib opening of the first barrier rib layer and is electrically connected to the barrier rib.

5. The display device of claim 1, wherein the upper auxiliary electrode does not contact the first barrier rib layer.

6. The display device of claim 1, wherein the indium zinc tin oxide (IZTO) comprises
an amount of indium atoms that is substantially the same as an amount of zinc atoms, and
tin atoms in an amount between equal to or greater than about 14 at % and equal to or less than about 22 at % based on a total of 100 at % of the IZTO.

7. The display device of claim 1, wherein the indium tin oxide (ITO) comprises indium oxide in a weight percent of about 90 wt % and tin oxide in a weight percent of about 10 wt % based on a total of 100 wt % of ITO.

8. The display device of claim 1, wherein the second barrier rib layer comprises a tip portion protruding from the first barrier rib layer toward the barrier rib opening.

9. The display device of claim 1, wherein the lower auxiliary electrode and the upper auxiliary electrode each comprise an amorphous crystal phase.

10. The display device of claim 1, wherein the lower auxiliary electrode extends along each of a first inner surface of the first barrier rib layer and a lower surface of the second barrier rib layer.

11. The display device of claim 1, wherein the lower auxiliary electrode and the upper auxiliary electrode each have a light transmittance of equal to or greater than about 90%.

12. A display device comprising:
a base layer;
a pixel defining film on the base layer and having a light emitting opening defined therein;
a barrier rib comprising a first barrier rib layer on the pixel defining film and a second barrier rib layer on the first barrier rib layer, and having a barrier rib opening defined therein, the barrier rib opening overlapping the light emitting opening;
a light emitting element overlapping the light emitting opening, and comprising a first electrode, a light emitting pattern on the first electrode and configured to emit light, and a second electrode on the light emitting pattern; and
an auxiliary electrode on the second electrode, contacting the barrier rib,
the auxiliary electrode comprising:
a lower auxiliary electrode on the second electrode, contacting the barrier rib, and comprising a transparent conductive oxide comprising zinc; and
an upper auxiliary electrode on the lower auxiliary electrode and comprising a transparent conductive oxide.

13. The display device of claim 12, wherein the lower auxiliary electrode and the upper auxiliary electrode each have a thickness between equal to or greater than about 50 Å and equal to or less than about 200 Å.

14. The display device of claim 12, wherein the lower auxiliary electrode comprises indium zinc tin oxide (IZTO), and the upper auxiliary electrode comprises indium tin oxide (ITO).

15. The display device of claim 14, wherein the indium zinc tin oxide (IZTO) comprises
an amount of indium atoms that is substantially the same as an amount of zinc atoms, and
tin atoms in an amount between equal to or greater than about 14 at % and equal to or less than about 22 at % based on a total of 100 at % of the IZTO.

16. The display device of claim 11, wherein the lower auxiliary electrode is on a first inner surface of the barrier rib opening of the first barrier rib layer and is electrically connected to the barrier rib.

17. A method for manufacturing a display device, the method comprising:
applying a preliminary display panel comprising a base layer, a pixel defining film on the base layer, a first preliminary barrier rib layer on the pixel defining film, and a second preliminary barrier rib layer on the first preliminary barrier rib layer;
etching the first preliminary barrier rib layer to form barrier rib openings defined therein and the second preliminary barrier rib layer to form barrier rib openings defined therein;
forming a light emitting element in the barrier rib openings, the light emitting element comprising a first electrode, a light emitting pattern, and a second electrode;
forming a lower auxiliary electrode contacting each of the second electrode and the barrier rib, and comprising indium zinc tin oxide (IZTO); and
forming an upper auxiliary electrode on the lower auxiliary electrode and comprising indium tin oxide (ITO).

18. The method of claim 17, wherein the forming of the light emitting element comprises a thermal evaporation process, and the forming of the lower auxiliary electrode and the forming of the upper auxiliary electrode each comprise a sputtering process.

19. The method of claim 17, wherein the lower auxiliary electrode and the upper auxiliary electrode each have a thickness between equal to or greater than about 50 Å and equal to or less than about 200 Å.

20. The method of claim 17, wherein the lower auxiliary electrode and the upper auxiliary electrode each comprise an amorphous crystal phase.
